(19) United States
(12) Patent Application Publication
(10) Pub. No.: US 2015/0269995 A1
(43) Pub. Date: Sep. 24, 2015

(54) SEMICONDUCTOR DEVICE

(71) Applicants: Kazuhiko KAJIGAYA, Tokyo (JP); PS4 LUXCO S.A.R.L., Luxembourg (LU)

(72) Inventor: Kazuhiko Kajigaya, Tokyo (JP)

(73) Assignee: PS4 Luxco S.a.r.l., Luxembourg (LU)

(21) Appl. No.: 14/430,449

(22) PCT Filed: Sep. 20, 2013
(86) PCT No.: PCT/JP2013/005596

§ 371 Date: Mar. 23, 2015

(30) Foreign Application Priority Data
Sep. 24, 2012 (JP) 2012-209474

(51) Int. Cl. G11C 13/00; G11C 11/16

(52) U.S. Cl. CPC G11C 13/004; G11C 13/0069; G11C 11/1675; G11C 11/1673; G11C 2013/0078; G11C 2013/0045

(57) ABSTRACT

A semiconductor device comprises memory cell array including first memory cell connected between first terminal and second terminal, written to first resistive state by applying voltage in first direction to first memory cell, and written to second resistive state by applying voltage in second direction different from first direction to first memory cell, first line and second line connected to first terminal and second terminal, respectively, third terminal receiving control signal, and first writing circuit comprising first input terminal connected to third terminal, second input terminal connected to one end of second line, and first output terminal connected to one end of first line, and first writing circuit being configured to control first line based on control signal of first input terminal and signal of second input terminal transmitted via second line.

### TECHNICAL FIELD

### Cross-Reference to Related Applications

This application is based upon and claims the benefit of the priority of Japanese patent application No. 2012-209474, filed on Sep. 24, 2012, the disclosure of which is incorporated herein in its entirety by reference thereto. The present invention relates to a semiconductor device. Particularly, the present invention relates to a semiconductor device comprising a variable resistance memory cell.

### BACKGROUND ART

As a present-day non-volatile semiconductor memory device, a flash memory is extensively used. Investigations into a variety of semiconductor memory devices, for purpose of taking the place of the flash memories, are now going on. In particular, a variable resistance memory cell storing information of logical value 0 or 1 by a resistive state of a variable resistance element is known.

Writing data in a variable resistance element has two different sorts, one of which is a write of changing a high resistance state to a low resistance state, and the other being a write of changing a low resistance state to a high resistance state. In the present description, it is assumed that a low resistance state is logical value 1, while a high resistance state is logical value 0. Here, it is known that in a bipolar-type variable resistance memory cell, a voltage/current is applied to the variable resistance element in the opposite direction for writing information of logical value 0 and writing information of logical value 1.

For instance, as various bipolar-type variable resistance elements, there are a STT-RAM (Spin Transfer Torque-Random Access Memory) in which writing is performed by a spin injection magnetization reversal using a MTJ (Magnetic Tunnel Junction) element, and a Re-RAM (Resistive-Random Access Memory) using metal oxides etc.

In the above-mentioned STT-RAM, a rewrite operation to a memory cell is known.

Patent Literatures 1 and 2 disclose control methods attempting to solve a problem that data stored in a memory cell from which has been read out is reversed due to disturbing current during read operation. In the control methods data which has been read out by a sense amplifier is latched, and the latched data is rewritten to the memory cell.

### CITATION LIST

### Patent Literature

PTL 1: JP Patent Kokai Publication No. JP-P2009-230798A (US Patent Application Publication No. US 2009/0237988A)
PTL 2: JP Patent Kokai Publication No. JP-P2011-65701A

### SUMMARY OF INVENTION

### Technical Problem

The disclosures of the above cited Patent Literatures are incorporated herein in their entirety by reference thereto. The analyses below are presented in the view point of the present disclosure.

However, in Patent Literatures 1 and 2, circuits of a latch for rewriting and two writing circuits are arranged on one side of the memory cell array (that is, one end of the right end and the left end in each of bit lines). Thus, line resistance value resulting by adding parasitic resistances of a bit line and a source line that appear on a writing current path during a rewrite operation varies, depending on the position of a memory cell on a bit line source line pair.

As the result, the following problems occur. In case where a constant current type drive circuit is used as a writing circuit, there is a problem that the output voltage range of the constant current type writing circuit must be set to a large value, so that a power supply voltage becomes high, which causes the power consumption to increase. And, in case where a constant voltage type drive circuit is used as the writing circuit, there is a problem that the writing current varies depending on the position of the memory cell, which brings about decrease in the writing margin.

Other tasks and new features will become apparent by disclosure of the present description and attached drawings.

### Solution to Problem

According to a first aspect of the present disclosure, there is provided a semiconductor device comprising a memory cell array including a first memory cell connected between a first terminal and a second terminal, written to a first resistive state by applying a voltage in a first direction to the first memory cell, and written to a second resistive state by applying a voltage in a second direction different from the first direction to the first memory cell, a first line and a second line connected to the first terminal and the second terminal, respectively, a third terminal receiving a control signal, and a first writing circuit comprising a first input terminal connected to the third terminal, a second input terminal connected to one end of the second line, and a first output terminal connected to one end of the first line, and the first writing circuit being configured to control the first line based on the control signal of the first input terminal and a signal of the second input terminal transmitted via the second line.

### Advantageous Effects of Invention

The meritorious effects of examples of the present disclosure are summarized as follows without limitation thereto. According to examples of the semiconductor device of the present disclosure, in a memory cell array using bipolar type variable resistance memory cells, in case where a constant current type writing drive circuit is used, a power supply voltage can be lowered. On the other hand, in case where a constant voltage type writing drive circuit is used, a writing margin can be improved.

### BRIEF DESCRIPTION OF DRAWINGS

FIG. 1 is a block diagram showing an entire configuration of a semiconductor device in accordance with a first exemplary embodiment.

FIG. 2 is a diagram illustrating a principle of writing control of the semiconductor device in accordance with the first exemplary embodiment.

FIG. 3 is a diagram illustrating an entire structure of a chip of the semiconductor device in accordance with the first exemplary embodiment.

FIG. 4 is a diagram illustrating a structure of one bank of the semiconductor device in accordance with the first exemplary embodiment.

FIG. 5 is a diagram illustrating a structure of one array of the semiconductor device in accordance with the first exemplary embodiment.

FIG. 6 is a diagram illustrating a structure of one mat of the semiconductor device in accordance with the first exemplary embodiment.

FIG. 7 is a diagram illustrating a structure of one sub-mat of the semiconductor device in accordance with the first exemplary embodiment.

FIG. 8 is a circuit diagram of a RWC (reading/writing control circuit) of the semiconductor device in accordance with the first exemplary embodiment.

FIG. 9 is a circuit diagram of a first writing circuit in FIG. 8.

FIG. 10 is a circuit diagram showing detail of a sense latch circuit in FIG. 8.

FIG. 11 is a waveform chart showing an operation of GBL->GCS write of the semiconductor device in accordance with the first exemplary embodiment.

FIG. 12 is a waveform chart showing an operation of GCS->GBL write of the semiconductor device in accordance with the first exemplary embodiment.

FIG. 13 is a waveform chart showing an operation of the sub-mat of the semiconductor device in accordance with the first exemplary embodiment.

FIG. 14 is a waveform chart showing an operation of GBL->GCS write of the semiconductor device in accordance with a variant of the first exemplary embodiment.

FIG. 15 is a waveform chart showing an operation of GCS->GBL write of the semiconductor device in accordance with the variant of first exemplary embodiment.

FIG. 16 is a waveform chart showing an operation of the sub-mat of the semiconductor device in accordance with the variant of first exemplary embodiment.

FIG. 17 is a circuit diagram of a RWC (reading/writing control circuit) of the semiconductor device in accordance with a second exemplary embodiment.

FIG. 18 is a circuit diagram of a first writing circuit of the semiconductor device in accordance with the second exemplary embodiment.

FIG. 19 is a waveform chart showing an operation of GBL->GCS write of the semiconductor device in accordance with the second exemplary embodiment.

FIG. 20 is a waveform chart showing an operation of GCS->GBL write of the semiconductor device in accordance with the second exemplary embodiment.

FIG. 21 is a waveform chart showing an operation without rewriting in the semiconductor device in accordance with the second exemplary embodiment.

FIG. 22 is a waveform chart showing an operation of a sub-mat of the semiconductor device in accordance with the second exemplary embodiment.

FIG. 23 is a block diagram showing a configuration of an information processing system in accordance with a third exemplary embodiment.

### DESCRIPTION OF EMBODIMENTS

An outline of an example of the present disclosure will be described. Meanwhile, drawing reference symbols referred in the following outline are shown only by way of example to assist understanding, and are not intended to limit the present disclosure to the illustrated modes. Various exemplary embodiments other than the following outline are possible.

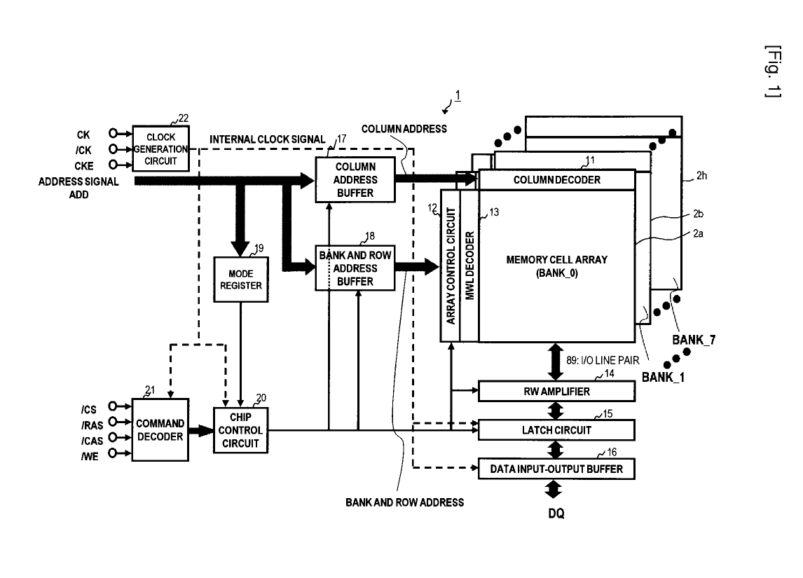

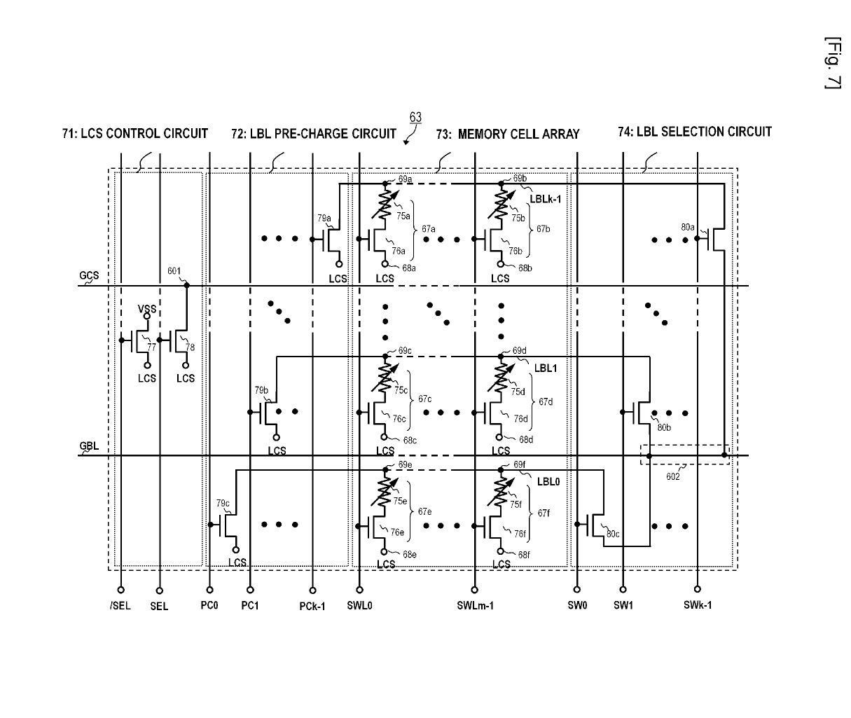

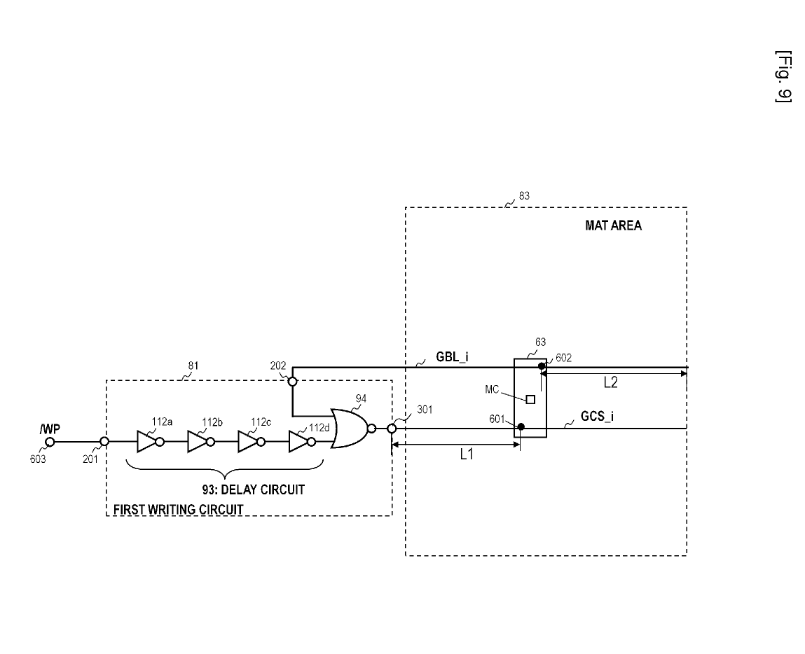

A semiconductor device 1 according to one exemplary embodiment of the present disclosure comprises: a memory cell array (2a-h in FIG. 1 etc.) including memory cells (67a-f in FIG. 7) each connected between a first terminal (68a-f in FIG. 7) and a second terminal (69a-f in FIG. 7), written to a first resistive state by applying a voltage in a first direction to the memory cell, and written to a second resistive state by applying a voltage in a second direction different from the first direction to the memory cell; a first line and a second line connected to the first and the second terminals, respectively; a first writing circuit (81 in FIG. 9) controlling the first line; and a third terminal (603 in FIG. 9) receiving a control signal (e.g., writing pulse signal) /WP in FIG. 9. If a memory cell array has a hierarchical bit line structure, the first line includes GCS (global common source line) and LCS (local common source line) in FIG. 7. If the memory cell array does not have a hierarchical bit line structure, the first line is constituted by a source line. If a memory cell array has a hierarchical bit line structure, the second line includes GBL (global bit line) and LBL0-LBLk−1 (local bit line) in FIG. 7. If the memory cell array does not have a hierarchical bit structure, the second line is constituted by a bit line. The first writing circuit 81 comprises: a first input terminal (201 in FIG. 9) connected to the third terminal 603; a second input terminal (202 in FIG. 9) connected to one end of the second line (one end of GBL_i in FIG. 9); and a first output terminal (301 in FIG. 9) connected to one end of the first line (one end of GCS_i in FIG. 9). The first writing circuit 81 is configured to control the first line based on the control signal (e.g., writing pulse signal) /WP of the first input terminal 603 and a signal of the second input terminal 202 transmitted via the second line.

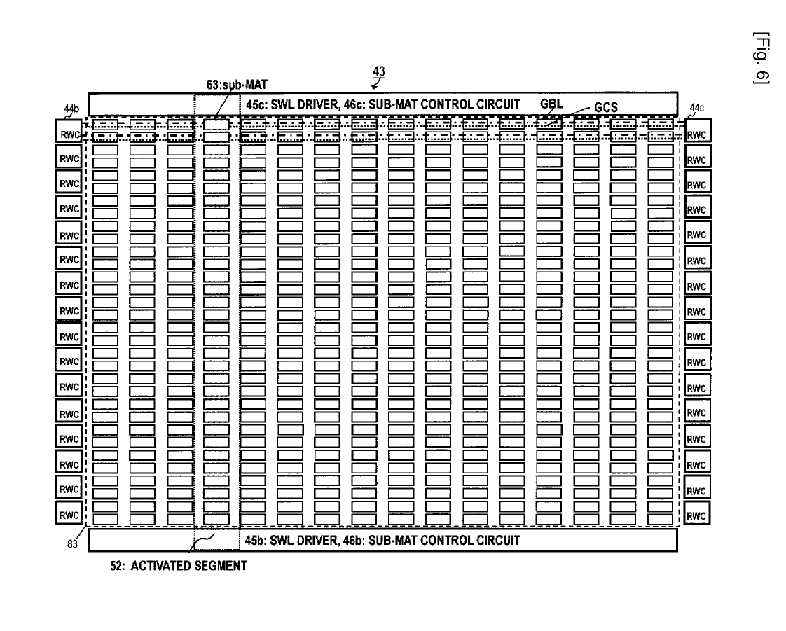

According to the above example of the present disclosure, upon writing or rewriting to a memory cell, it is possible that a length resulting by adding a length of the first line and a length of the second line on a writing current path is nearly constant regardless of the position of the memory cell. By referring FIG. 9, the reason will be described below. As shown in FIG. 9, one MAT area (83 in FIGS. 6, 9) includes a plurality of sub-MATs (63 etc. in FIGS. 6, 9), and each of the sub-MATs is connected to GCS_i (global common source line) and GBL_i (global bit line). And in a sub-MAT, each of memory cells is connected to a local line. In this case, the length resulting by adding the length of GCS_i (L1) and the length of GBL_i (L2) on the writing current path remains at the same value for arbitrary sub-MATs arranged in the MAT area (83 in FIGS. 6, 9). Therefore, it is possible that the length resulting by adding the length of first line and the length of second line on the writing current path for arbitrary memory cell(s) is nearly constant regardless of the position of the memory cell to be written.

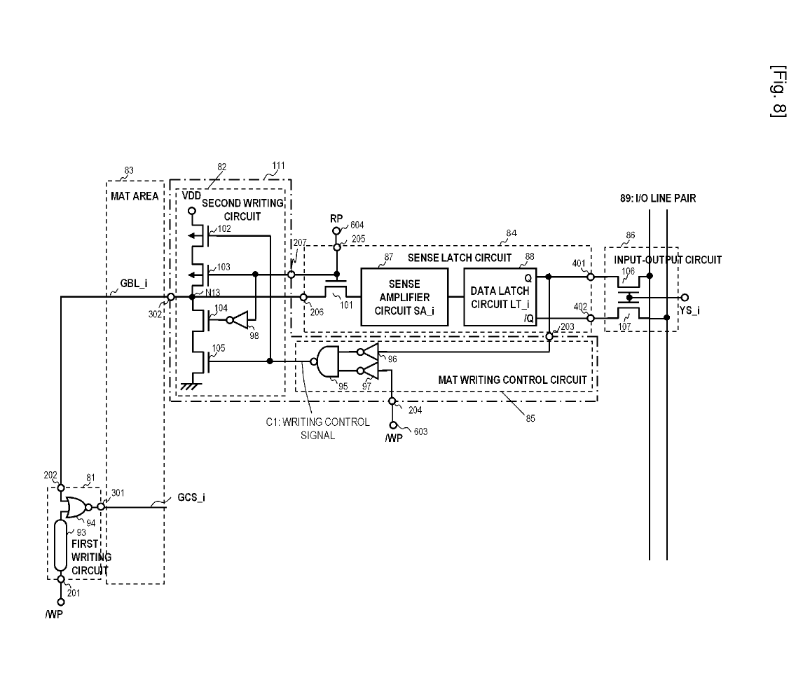

According to the above example of the present disclosure, upon rewriting to a memory cell (when the control signal (e.g., writing pulse signal) /WP in FIG. 9 is active), the first writing circuit 81 controls the first line based on a signal transmitted via a bit line, i.e., a logical level determined by the latched data in FIG. 8. In this case, a logical signal determined by the latched data is not transmitted via a signal line routed in the peripheral region of the memory cell array, but transmitted via a bit line to the first writing circuit 81.

There are examples according to the present disclosure. As shown in FIG. 9, in the above semiconductor device 1, when the control signal (e.g., writing pulse signal) /WP is active, the first writing circuit 81 may invert a first potential of the second line to output an inverted one of the first potential as a potential of the first output terminal 301.

As shown in FIG. 8, the above semiconductor device 1 may further comprise a writing unit (111 in FIG. 8; an area enclosed by a dashed line) controlling the second line (line including GBL_i). The writing unit 111 may include a third input terminal 203 receiving write data, a fourth input terminal 204 receiving the control signal (e.g., writing pulse signal) /WP, and a second output terminal 302 connected to the other end of the second line. The writing unit 111 may be configured to control the second line (line including GBL_i) based on the write data of the third input terminal 203 and the control signal (e.g., writing pulse signal) /WP of the fourth input terminal 204.

As shown in FIG. 8, the above semiconductor device 1 may further comprise a reading circuit 84 reading out data from the second line, and a pair of I/O lines (e.g., I/O line pair 89). The reading circuit 84 may include a first input-output terminal 401 and a second input-output terminal 402 connected to respective lines of the I/O lines 89; and the first input-output terminal 401 of the reading circuit 84 may be connected to the third input terminal 203 of the writing unit 111 so that the writing unit 111 receives write data from the first input-output terminal 401 of the reading circuit 84.

The write data, which the writing unit 111 receives from the first input-output terminal 401 of the reading circuit 84, may be data which has been read out from the memory cell (67a-f in FIG. 7 etc.).

As shown in FIG. 8, the above semiconductor device 1 may further comprise a fourth terminal 604 receiving a read control signal (e.g., reading pulse signal RP). The reading circuit 84 may further include a fifth input terminal 205 connected to the fourth terminal 604, and a six input terminal 206 connected to the second line and the second output terminal 302 of the writing unit. Here, the reading circuit 84 may further include: a sense amplifier circuit 87 including an input node and an output node; a first transistor 101 including a gate connected to the fifth input terminal 205 and a source-drain path connected between the input node of the sense amplifier circuit 87 and the sixth input terminal 206; and a data latch circuit 88 including an input node connected to the output node of the sense amplifier circuit 87, and two output nodes (Q, /Q) being complementary from each other and connected respectively to the first and second input-output terminals (401, 402).

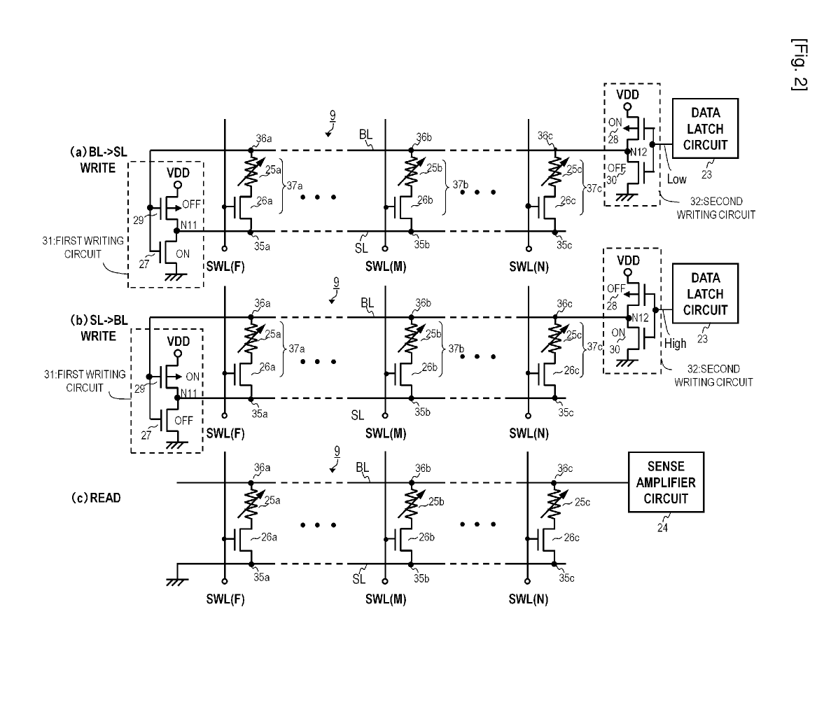

As shown in FIG. 8, in the above semiconductor device 1, the first line (line including GCS_i) and the second line (line including GBL_i) are arranged parallel to each other on the memory cell array and extends over the memory cell array (in FIG. 8, the first and second lines are disposed on the MAT area 83 of the memory cell array); and the one end of the first line (portion connected to the output terminal 301, e g., left end of SL in FIG. 2) and the other end of the first line (e g., right end of SL in FIG. 2) are arranged on opposite sides of the memory cell array from each other, and the one end of the second line (e g., left end of BL in FIG. 2) and the other end of the second line (portion connected to the output terminal 302, e g., right end of BL in FIG. 2) are arranged on opposite sides of the memory cell array from each other. That is to say, the first writing circuit 81 and the writing unit 111 are disposed across the MAT area 83 and connected to the first line and the second line respectively.

As shown in FIG. 8, in the above semiconductor device 1, the writing unit 111 may include a seventh input terminal 207 connected to the fourth terminal 604, a writing control circuit 85, and a second writing circuit 82. Here, the writing control circuit 85 may produce a writing control signal C1 based on the write data of the third input terminal 203 and the control signal (e.g., writing pulse signal) /WP of the fourth input terminal 204; and the second writing circuit 82 may be configured to control the second line (line including GBL_i) based on the reading pulse signal RP of the seventh input terminal 207 and the writing control signal C1 produced by the writing control circuit.

As shown in FIG. 9, in the above semiconductor device 1, the first writing circuit 81 may include: a delay circuit 93 including an input node and an output node, the input node of the delay circuit being connected to the first input terminal 201; and a first NOR logical circuit 94 including a plurality of input nodes respectively connected to the second input terminal 202 and an output node of the delay circuit 93, and an output node connected to the first output terminal 301.

As shown in FIG. 8, in the above semiconductor device 1, the writing control circuit 85 of the writing unit 111 may include: a NAND logical circuit 95 including an output node outputting the writing control signal C1; a first inverter circuit 96 including an input node connected to the third input terminal 203, and an output node connected to one input node of the NAND logical circuit 95; and a second inverter circuit 97 including an input node connected to the fourth input terminal 204, and an output node connected to the other input node of the NAND logical circuit 95.

As shown in FIG. 8, in the above semiconductor device 1, the second writing circuit 82 of the writing unit 111 may include: second and third transistors (102, 103) being of a first conductive type and being connected between a power supply VDD and the second output terminal 302, a gate of the second transistor 102 being supplied with the writing control signal, and a gate of the third transistor 103 being connected to the fifth input terminal 205; and fourth and fifth transistors (104, 105) being of a second conductive type and being connected between the second output terminal 302 and ground, a gate of the fourth transistor 104 being connected to the fifth input terminal 205 via a third inverter circuit 98, and a gate of the fifth transistor 105 being supplied with the writing control signal C1.

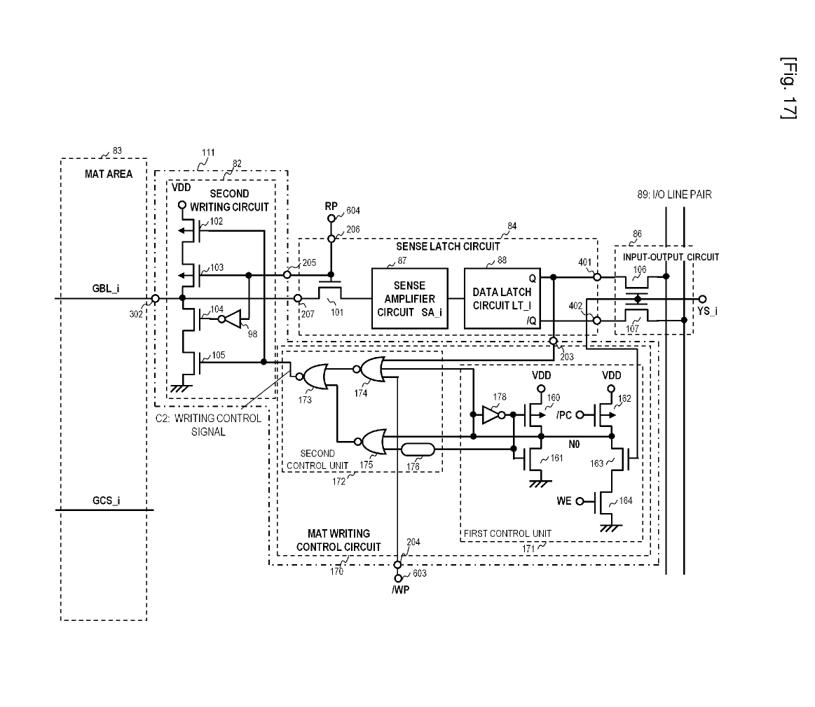

As shown in FIG. 17, in the above semiconductor device 1, a writing control circuit 170 of the writing unit 111 (constitution in which the writing control circuit 85 in FIG. 8 is replaced with a writing control circuit 170 in FIG. 17) may include: a first rewrite node NO; a first control unit 171 to which a pre-charge signal /PC, a selection signal YS_i, and a write enable signal WE are supplied; and a second control unit 172 to which the write data and the control signal (e.g., writing pulse signal) /WP are supplied. The first control unit 171 may control the first write node NO based on the supplied pre-charge signal /PC, the supplied selection signal YS_i, and the supplied write enable signal WE; and the second control unit 172 may generate the writing control signal C2 based on the supplied write data, the supplied control signal (e.g., writing pulse signal) /WP, and a potential of the first rewrite node NO.

As shown in FIG. 17, the second control unit 172 of the writing control circuit 170 of the writing unit 111 may include: a second NOR logical circuit 173 outputting the write control signal C2; a third NOR logical circuit 174 including a plurality of input nodes connected to the third input terminal 203, the fourth input terminal 204, and the first rewrite node NO respectively, and an output node connected to one input node of the second NOR logical circuit 173; and a fourth NOR logical circuit 175 including a plurality of input nodes connected respectively to the first rewrite NO, a connecting node connected to the first rewrite node NO via the fourth inverter 178 and the delay circuit 176, and an output node connected to the other input node of the second NOR logical circuit 173.

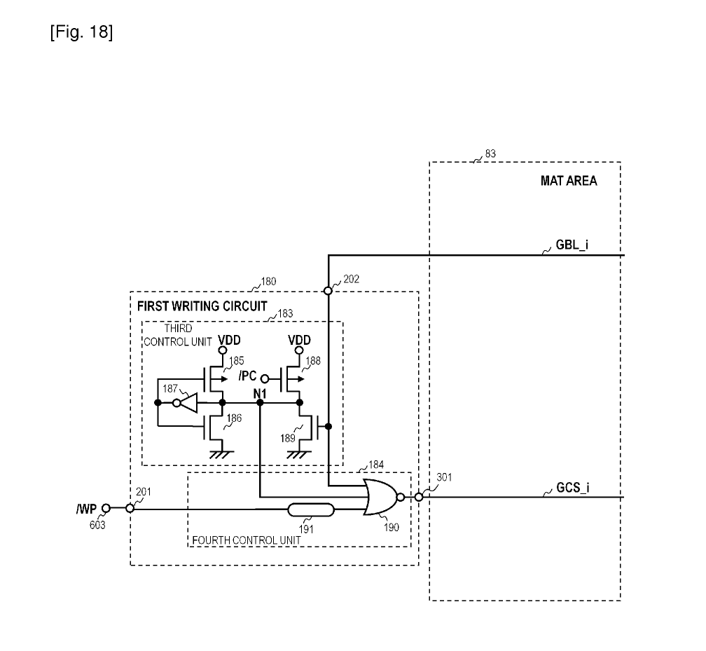

As shown in FIG. 18, in the above semiconductor device 1, the first writing circuit 180 (constitution in which the first writing circuit 81 in FIG. 9 is replaced with the first writing circuit 180 in FIG. 18) may include: a second rewrite node N1; a third control unit 183 to which the pre-charge signal /PC and a signal transmitted via the second line (line including GBL_i) are supplied; and a fourth control unit 184 to which a signal transmitted via the second line (line including GBL_i) and the control signal (e.g., writing pulse signal) /WP are supplied. The third control unit 183 may control the second rewrite node N1 by the supplied pre-charge signal /PC and the supplied signal transmitted via the second line; and the fourth control unit 184 may control the first line based on the supplied signal transmitted via the second line, the supplied control signal (e.g., writing pulse signal) /WP, and a level of the second rewrite node N1.

The fourth control unit 184 of the first writing circuit 180 may include: a delay circuit 191 including an input node connected to the first input terminal 201; and a fifth NOR logical circuit 190 including a plurality of input nodes connected to the second input terminal 202, an output node of the delay circuit 191, and the second rewrite node N1 respectively, and an output node connected to the first output terminal 301.

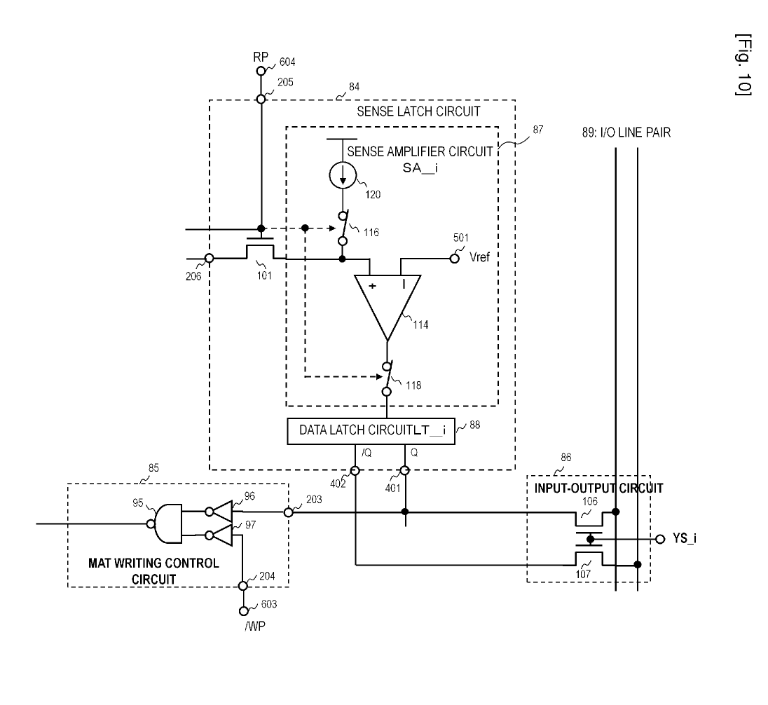

As shown in FIG. 10, in the above semiconductor device 1, the sense amplifier circuit 87 of the reading circuit 84 may include: a reading current circuit 120 connected to a power supply; a differential amplifier circuit 114 including one input node connected to one end (one of drain and source) of the first transistor 101; a first switch circuit 116 connected between the reading current circuit 120 and one input node of the differential amplifier circuit 114, and controlled by the reading pulse signal RP; a reference terminal 501 connected to the other input node of the differential amplifier circuit 114, and receiving a reference voltage Vref; and a second switch circuit 118 connected between an output node of the differential amplifier circuit 114 and the data latch circuit 88, and controlled by the reading pulse signal RP.

As shown in FIG. 7, in the above semiconductor device 1, the first and second lines may have hierarchical structures respectively; the first line may include a global common source line GCS and a local common source line LCS having a lower hierarchy of the global common source line GCS; the second line may include a global bit line GBL and local bit lines LBL0 to LBLk−1 having a lower hierarchy of the global bit line GBL; the local common source line LCS of the first line is connected to the first terminals of the memory cells 68a-f. As shown in FIG. 8, the first writing circuit 81 may be configured to control the global common source line GCS_i of the first line; and the writing unit 111 may be configured to control the global bit line GBL_i of the second line.

As shown in FIG. 8, the above semiconductor device 1 may further comprise an input-output circuit 86 inserted between the I/O line pair 89 and the first and second input-output terminals (401, 402) of the reading circuit 84. The input-output circuit 86 may be configured to provide one of conductive and non-conductive states between the I/O line pair 89 and the first and second input-output terminals (401, 402) in response to a selection signal YS_i.

As shown in FIG. 6, in the above semiconductor device 1, the memory cell array includes a plurality of memory cells including the first memory cell, and the memory cells (e.g., memory cells 37a of a page region in FIG. 2) being arranged in a first row and being configured to receive written data (e.g., data of data latch circuits 23 in FIG. 2) arranged in the first row at a same time as each other.

In the above semiconductor device 1, the above memory cell(s) (67a-f in FIG. 7) may comprise a memory cell that includes a variable resistive element of any one of STT-RAM (Spin Transfer Torque-Random Access Memory) and Re-RAM (Resistive Random Access Memory).

The exemplary embodiments will now be described in details with reference to the drawings.

### First Exemplary Embodiment

### Constitution of First Exemplary Embodiment

Next, a configuration of a semiconductor device 1 will be described in details with reference to FIG. 1.

FIG. 1 illustrates an exemplary entire configuration of semiconductor device 1. The semiconductor device 1 shown in FIG. 1 includes memory cell arrays (2a-h) using STT-RAM (Spin Transfer Torque Random Access Memory), in which writing is performed by a spin injection magnetization reversal, as a variable resistance memory cell. The semiconductor device 1 includes external clock terminals CK, /CK, a clock enable terminal CKE, command terminals /CS, /RAS, /CAS, /WE, and data input-output terminal DQ. Meanwhile, in the description of the present invention, a signal to which “/” is added at the head of the signal name means an inverted signal of the relevant signal or means that the signal is low active. Therefore, CK, /CK are mutually complementary signals.

A clock generating circuit 22 receives external clock signals CK, /CK, and a clock enable signal CKE, and generates internal clock signals needed in the semiconductor device 1 to provide the internal clock signals to each unit.

A chip select signal /CS, a row address strobe signal /RAS, a column address strobe signal /CAS, a write enable signal /WE are supplied to the command terminals /CS, /RAS, /CAS, /WE, respectively. These command signals are supplied to a command decoder 21. The command decoder 21 decodes the received command signal to supply the decoded command signal to a chip control circuit 20.

An operation mode of the semiconductor device 1 is set in a mode register 19. The chip control circuit 20 receives an output of the command decoder 21 and the operation mode set in the mode register 19, and generates respective control signals based on the output of the command decoder 21 and the operation mode to supply the control signals to an array control circuit 12, RW (read-write) amplifier 14, a latch circuit 15, a data input-output buffer 16, a column address buffer 17, and a bank and row address buffer 18.

The address signal ADD includes a bank address specifying a bank, a row address specifying a word line (constituted by a main word line MWL and a sub word line SWL), and a column address specifying a bit line (constituted by a global bit line and a local bit line LBL). A bank address and a row address included in the address signal ADD are supplied to a bank and row address buffer 18, and a column address included in the address signal ADD is supplied to a column address buffer 17.

The bank and row address buffer 18 identifies one of banks 0-7, and outputs the row address. The row address outputted from the bank and row address buffer 18 is decoded by a MWL decoder 13, and one of main word lines MWLs is selected based on the result of decoding.

The column address outputted from the column address buffer is decoded by a column decoder 11, and one bit line corresponding to the column address is selected among a plurality of bit lines based on the result of decoding. A data latch circuit (88 in FIG. 8) in the memory cell array corresponding to the selected bit line is connected to a RW (read-write) amplifier 14 via an I/O line pair 89.

The RW amplifier 14 includes a reading amplifier circuit and a writing amplifier circuit connected to an input-output terminal DQ being an external terminal via the latch circuit 15 and the data input-output buffer 16. Here, an internal clock signal is supplied to the latch circuit 15 and the data input-output buffer 16 from the clock generating circuit 22, which controls the input-output timing between the memory cell array and the data input-output terminal DQ.

FIG. 2 illustrates exemplarily a principle of writing control of the semiconductor device in accordance the first exemplary embodiment. In order to simplify the explanation, it is assumed that a semiconductor device 9 does not have a hierarchical structure for bit lines BLs and source lines SLs. Referring to FIG. 2, a principle will be explained below that according to a constitution of semiconductor device 9, the length resulting by adding the length of first line and the length of second line on a writing current path is nearly constant regardless to the position of a memory cell to be written. As illustrated in FIG. 2, the semiconductor device 9 includes a plurality of memory cells 37a-c. Each of the memory cells 37a-c belongs to the memory cell array in FIG. 1 such as array 2a. Each of the memory cells 37a-c includes a variable resistance element 25a-c, and an NMOS transistor 26a-c connected in series to the variable resistance element 25a-c. A first terminal 35a-c and a second terminal 36a-c of each of memory cells 37a-c are connected to a source line SL (first line) and a bit line BL (second line), respectively. Sub-word lines (SWL(F), SWL(M), SWL(N) etc.) are connected to gates of the NMOS transistors 26a-c, respectively.

The semiconductor device 9 includes a first writing circuit 31, a second writing circuit 32, a data latch circuit 23, and a sense amplifier circuit 24. The above circuits 31, 32, 23 and 24 also belong to the memory cell array in FIG. 1 such as 2a. The first writing circuit 31 is an inverter circuit in which a PMOS transistor 29 and an NMOS transistor 27 are connected in series between a power supply VDD and the ground. Similarly, the second writing circuit 32 is also an inverter circuit in which a PMOS transistor 28 and an NMOS transistor 30 are connected in series between the power supply VDD and the ground.

As illustrated in FIG. 2, a pair of bit line BL and source line SL (hereafter also referred to as “bit line source line pair”) is disposed extending to the same direction. The first writing circuit 31 is disposed at one end of the bit line source line pair, while the data latch circuit 23 and the second writing circuit 32 are disposed at the other end of the bit line and source line pair. One end of the source line SL is connected to a node N11 which is an output node of the first writing circuit 31, and one end of the bit line BL is connected to gates of PMOS transistor 29 and NMOS transistor 27 which are input nodes of the first writing circuit 31. And the other end of the bit line BL is connected a node N12 which is an output node of the second writing circuit 32.

Next, an operation of the semiconductor device 9 will be described.

FIG. 2 (a) illustrates a write operation of bit line BL->source line SL. When a write operation is performed by flowing current in the direction of bit line BL->source line SL (e.g., the current flows from bit line BL to source line SL), write data for the data latch circuit 23 is set to be Low level. The PMOS transistor 28 of the second writing circuit 32 disposed on the same side as the data latch circuit 23 is in an on state, whereas the NMOS transistor 30 is in an off state, so that the bit line BL is driven to High level by the PMOS transistor 28. The High level signal is transmitted to the input node of the first writing circuit 31 disposed on the opposite side of the data latch circuit 23 via the bit line BL, so that the PMOS transistor 29 is in an off state, whereas the NMOS transistor 27 is in an on state. From the above, the source line is driven to Low level by the NMOS transistor 27. As mentioned above, the first writing circuit 31 drives the source line SL by inverting the signal transmitted via the bit line BL.

If a sub-word line such as SWL(M) among a plurality of sub-word lines is selected to be High level, a write operation is performed by flowing current in the direction of the bit line BL->the memory cell 37b->the source line SL.

Next, FIG. 2 (b) illustrates a write operation of source line SL->bit line BL. When a write operation is performed by flowing current in the direction of source line SL->bit line BL (e.g., the current flows from source line SL to bit line BL), write data for the data latch circuit 23 is set to be High level. In this case, the PMOS transistor 28 is in an off state, whereas the NMOS transistor 30 is in an on state, so that the bit line BL is driven to Low level. The Low level signal is transmitted to the input node of the first writing circuit 31 via the bit line BL, and the first writing circuit 31 drives the source line SL to High level by reversing the signal.

If a sub-word line such as SWL(M) among a plurality of sub-word lines is selected to be High level, a write operation to the selected memory cell (memory cell 37b) is performed by flowing current in the direction of source line SL->the selected memory cell (memory cell 37b)->bit line BL.

Next, FIG. 2 (c) illustrates a read operation. During a read operation, a control circuit (not shown) controls the other end of bit line BL to be connected to a sense amplifier circuit 24 instead of the second writing circuit 32. A sense-amplifying is performed by flowing reading current in the direction of the sense amplifier circuit 24->the bit line BL->the selected memory cell->the source line SL, and comparing a voltage of the bit line BL varied by the reading current with a reference value.

Next, the length of writing current path during the write operations of FIGS. 2 (a), 2 (b) will be considered below. First, if the selected memory cell is the memory cell 37a, the writing current path includes the node N11 to the first terminal 35a of the source line SL, and the second terminal 36a to the node N12 of the bit line BL. Next, if the selected memory cell is the memory cell 37b, the writing current path includes the node N11 to the first terminal 35b of the source line SL, and the second terminal 36b to the node N12 of the bit line BL. If the selected memory cell is the memory cell 37c, the writing current path includes the node N11 to the first terminal 35c of the source line SL, and the second terminal 36c to the node N12 of the bit line BL. From the above, it turns out that the length resulting by adding the length of source line SL and the length of bit line BL on the writing current path is constant.

On the other hand, as disclosed in Patent Literatures 1, 2, if the first writing circuit 31 and the second writing circuit 32 are disposed on the same side (for instance, both circuits are disposed on the side of second writing circuit 32), a problem occurs that the length resulting by adding is not constant as follows: if a memory cell (37a etc.) far from the first and the second writing circuits is selected, the length resulting by adding the length of source line SL and the length of bit line BL on the writing current path becomes longer. Whereas, a memory cell (37c) near the first and the second writing circuits is selected, the length resulting by adding the length of source line SL and the length of bit line BL on the writing current path becomes shorter.

In the semiconductor device 9, if sheet resistance of bit line BL is set to be equal to that of the source line SL by selecting material properties, thicknesses, line widths of the two lines, it is possible that the parasitic resistance value on the writing current path is nearly constant. As the result, if a constant voltage drive-typed writing circuit is adopted as illustrated in FIG. 2, an effect of improving a writing margin is brought about. Alternatively, if a constant current drive-typed writing circuit is adopted, an effect is brought about that the power supply voltage can be lowered.

Besides, in case where a rewrite operation is supported in FIGS. 2 (a), 2 (b), a signal outputted from the latch is not transmitted via a signal line routed in a peripheral area of memory area but via the bit line BL in the memory area, to the first writing circuit 31. Since a signal line routed in the peripheral area of memory area is not provided, an effect is brought about that a layout area is smaller than in case where a signal line is routed.

Meanwhile, the semiconductor device 9 has a constitution in which the second writing circuit 32 drives the bit line BL in response to write data, and the first writing circuit 31 controls the source line SL based on a signal transmitted via the bit line BL. However, a constitution, in which roles of bit line BL and source line SL are exchanged, is possible. That is to say, the second writing circuit 32 may drive the source line SL based on the write data, and the first writing circuit 31 may control the bit line BL based on a signal transmitted from the source line SL.

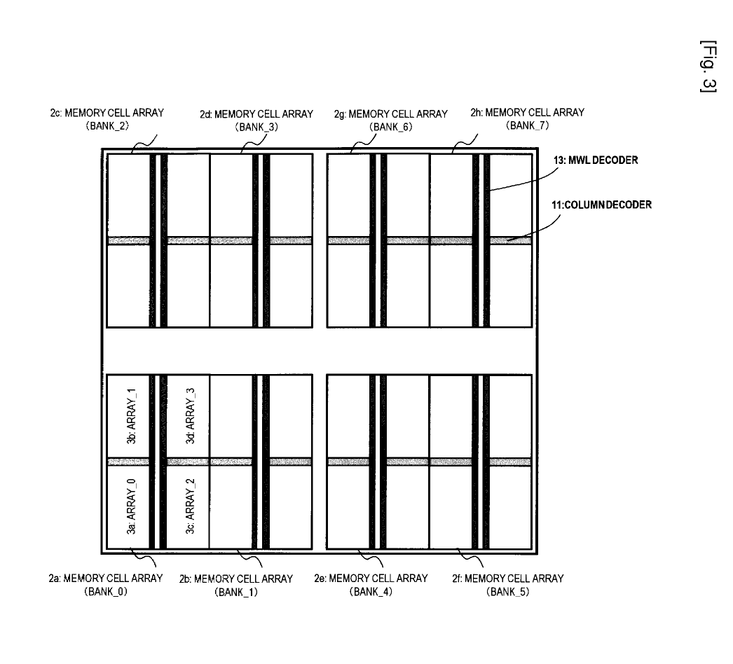

FIG. 3 illustrates an example of an entire structure of a chip in the semiconductor device 1 in accordance with the first exemplary embodiment. As shown in FIG. 3, there are eight banks in the chip. MWL (main word line) decoders 13 formed in two-columns are vertically disposed in a center of each bank, and a column decoder 11 is horizontally disposed in the center of each bank. Array_0-3 (3a-d) are disposed at four areas separated by the MWL decoders 13 and the column decoder 11.

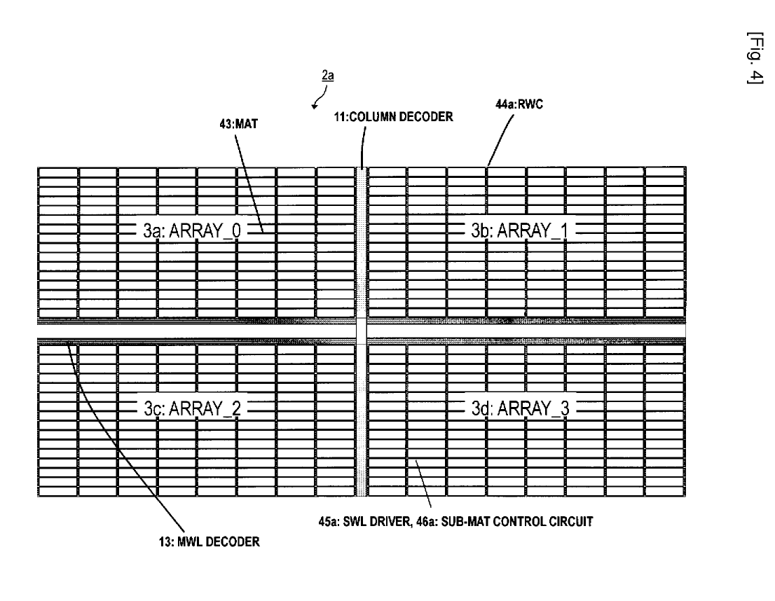

FIG. 4 illustrates an exemplary structure of one bank of the semiconductor device 1 such as bank_0 (2a) in FIG. 3 after rotating 90 degrees. Each of the four array_0-3 (3a-d) is separated to 128 MATs (43 etc.) in total by dividing into eight horizontally and dividing into sixteen vertically. Sub-word line SWL drivers 45a and sub-MAT control circuits 46a are disposed at the top-side and the bottom-side of each of the MATs, and reading/writing control circuits RWCs (44a etc.) are disposed at the right side and the left side of each of the MATs. Although there are no limitations, the sub-MAT control circuits (46a etc.) and RWCs (44a etc.) are shared between adjacent MATs.

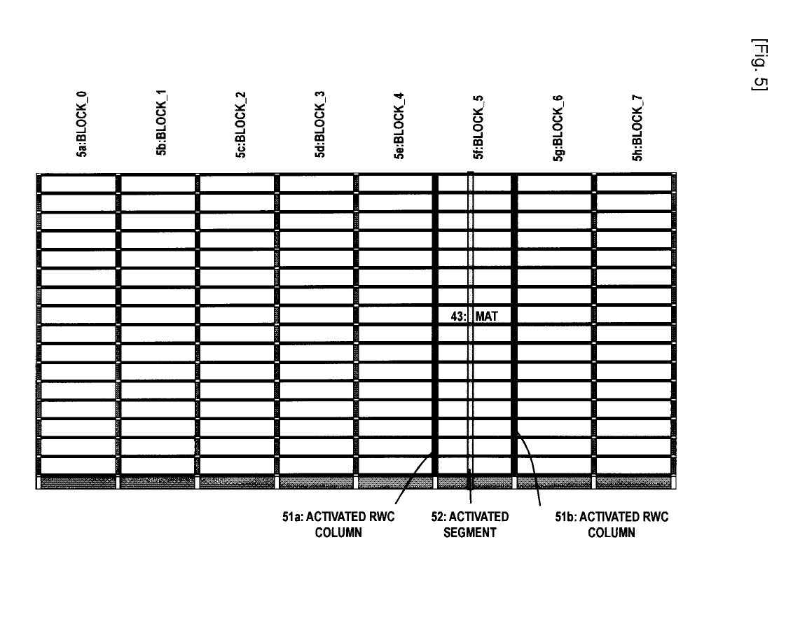

FIG. 5 illustrates an exemplary structure of one array in FIG. 4. An array is separated to eight blocks BLOCK_0-7 (5a-5h) each of which includes a column with sixteen MATs arranged in the vertical direction. As shown in FIG. 5, when a memory cell is accessed, in each of the four arrays in a bank, a segment 52 in a block is selected (the selected segment is also referred to as “activated segment”), and RWC columns 51a, 51b disposed at both sides of the segment are activated (the activated RWC column is also referred to as “activated RWC column”). Thus, totally, eight activated RWC columns are generated in a bank, which constitutes an open page that will be described later. However, memory access is not restricted to the above-mentioned open page constitution. For instance, only a single memory cell may be selected.

FIG. 6 illustrates an exemplary structure of one mat MAT 43 in FIG. 5. As shown in FIG. 6, a MAT is separated to 512 sub-MATs in total by dividing into sixteen horizontally and dividing into thirty-two vertically (here, the area including 512 sub-MATs in one mat MAT 43 is referred to as a MAT area 83). The sub-MATs disposed in-line vertically constitutes one activated segment 52 mentioned above, and only the activated segment 52 arranged in MAT43 is illustrated in FIG. 6. A sub-MAT in the activated segment 52 among sixteen sub-MATs disposed horizontally is selectively connected to the RWCs disposed at both ends of the MAT via a global bit line GBL and a global common source line GCS. For instance, in FIG. 6, a sub-MAT 63 in the activated segment 52 among sixteen sub-MATs in the most top line is selectively connected to RWCs 44b, 44c disposed at both ends of the line.

The MAT area 83 is separated to sub-MATs as mentioned above, and bit lines are hierarchically structured by global bit lines GBLs and local bit lines LBLs as shown in FIG. 7, which brings about such an effect that the affection of resistance of local bit lines LBLs formed by relatively high resistance material can be reduced. Similarly, source lines are hierarchically structured by global common source lines GCSs and local common source lines LCSs, which brings about such an effect that the affection of resistance of local common source lines LCSs formed by relatively high resistance material can be reduced. Besides, since the local common source lines LCSs are shared among all memory cells in the sub-MAT, an effect is brought about that the resistance of the local common source lines can be further reduced.

Sixteen RWCs (thirty-two RWCs in total) are respectively disposed at both sides of one MAT, and if a word line is selected, these thirty-two RWCs are selected at the same time. That means that 512 RWCs are selected in one array (in FIG. 5, each of the activated RWC columns 51a, 51b includes 256 RWCs, respectively). Thus, since one bank includes four arrays, if a word line is selected, 2048 RWCs are selected, so that a page with 2048 bits (256 bytes) is opened.

A signal line of writing pulse signal (control signal) /WP is commonly routed in the vertical direction of the figure per sixteen RWCs disposed at left and right ends of the MAT in FIG. 6. MATs adjacent in the vertical direction may use the same signal line. That is to say, a single signal line may be used per RWC column in FIG. 5. Upon a rewrite operation, since the rewrite operation is performed by driving a plurality of RWCs at the same time, the common signal line can be used for the transmission of writing pulse signal (control signal) /WP.

Meanwhile, sense amplifier circuits (87 in FIG. 87) in RWCs are disposed alternately for each of the GBL-GCS pairs. For instance, a sense amplifier circuit 87 arranged at a right-sided RWC 44c is connected to a GBL-GCS pair disposed at the most top line in FIG. 6, and a sense amplifier circuit 87 arranged at a left-sided RWC 44b is connected to a GBL-GCS pair disposed at the second line. Besides, a first writing circuit (81 in FIG. 9) is connected to each of GCSs in areas in which sense amplifier circuits 87 are not arranged, and a second writing circuit (82 in FIG. 8) is connected to each of GBLs in areas in which sense amplifier circuits 87 are arranged.

FIG. 7 illustrates an exemplary structure of one sub-MAT 63 in FIG. 6. A sub-MAT 63 includes a LCS (local common source line) control circuit 71, an LBL (local bit line) pre-charge circuit 72, a memory cell array 73, and an LBL (local bit line) selection circuit 74. Here, the memory cell array 73 is one sub-MAT which is a two-dimensionally disposed memory cell array, which is different from the memory cell arrays (2a-h) per bank unit in FIG. 1 with respect to a specified area.

The memory cell array 73 includes m sub-word lines SWL0 to SWLm−1, k local bit lines LBL0 to LBLk−1, and m*k variable resistance memory cells (67a-f) disposed at the points of intersection of the sub-word lines and the local bit lines. Meanwhile, as shown in FIG. 6, sixteen sub-MATs are connected to a GBL-GCS pair, and RWCs are connected to one end of GCS (left side in FIG. 6) and the other end of GBL (right side in FIG. 6), respectively.

The LCS control circuit 71 includes an NMOS transistor 78 whose gate is connected to a segment selection signal SEL, and an NMOS transistor 77 whose gate is connected to a reversed segment selection signal /SEL. In case where the semiconductor device 1 is in a pre-charge state and the segment is in a non-selective state, SEL, /SEL are controlled to be Low level, High level, respectively, so that the LCS (local common source line) is controlled to be the pre-charge potential VSS, and the LCS is electrically disconnected to the GCS. In case where the segment is selected, SEL, /SEL are controlled to be High level, Low level, respectively, so that the LCS is electrically disconnected to the VSS, and electrically connected to the GCS.

The LBL pre-charge circuit 72 includes k pre-charge transistors 79a-c whose gates are connected to k pre-charge signals PC0 to PCk−1 for k LBLs (local bit line), respectively. If each of the pre-charge signals PC0 to PCk−1 is controlled to be High level, the LBL0 to LBLk−1 are electrically connected to the LCS, respectively, to be pre-charged to VSS. In case where a segment is selected to be activated, only a pre-charge signal corresponding to the selected one LBL is controlled to be Low level, so that the selected LBL is electrically disconnected to the LCS.

The LBL selection circuit 74 includes k connection NMOS transistors 80a-c whose gates are connected to k connection signals SW0 to SWk−1 corresponding to the k LBLs, respectively. If the semiconductor device 1 is in a pre-charge state, the connection signals SW0 to SWk−1 are controlled to be Low level, so that each of the LBLs is electrically disconnected from the GBL. In case where a segment is selected and activated, only a connection signal corresponding to the selected one LBL is controlled to be High level, so only the selected LBL is electrically connected to the GBL.

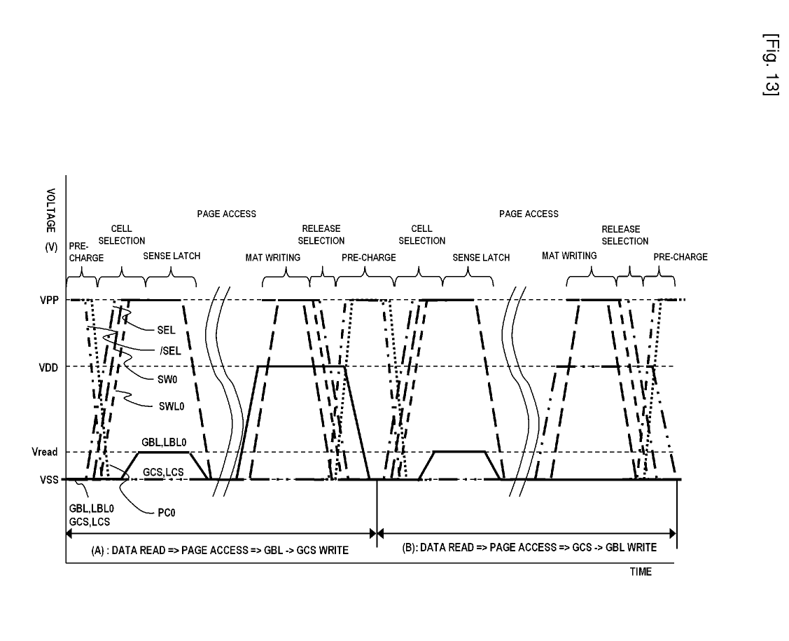

Meanwhile, in control signals /SEL, SEL, PC0 to PCk−1, SWL0 to SWLm−1 for the LCS control circuit 71, the LBL pre-charge circuit 72, the memory cell array 73, and the LBL selection circuit 74, High level and Low level are a potential VPP and a potential VSS, respectively (see FIG. 13).

In the sub-MAT in a selected and activated state, the LCS is electrically disconnected from VSS, and electrically connected to the GCS. The selected LBL is electrically disconnected from the LCS, and electrically connected to the GBL; other non-selective LBLs are electrically connected to the LCS. As for one memory cell (for instance, 67e) connected to the selected SWL and the selected LBL, the first terminal 68e of the memory cell is electrically connected to the first writing circuit (81 in FIG. 9) via the LCS and GCS, and the second terminal 69e of the memory cell is electrically connected to the second writing circuit (82 in FIG. 8) via the LBL0 and GBL.

On the other hand, as for other (k−1) memory cells connected to the selected SWL and the non-selected LBLs, both the first terminal (68a, 68c etc.) and the second terminal (69a, 69c etc.) are electrically connected to the LCS, so even if the NMOS transistors (76a, 76c etc.) are in an on state, voltage is not applied to the variable resistance elements (75a, 75c etc.), so that current does not flow through the variable resistance elements. Thus, as will be mentioned later, even if the LCS potential is driven to VDD or VSS, the information stored in the variable resistance elements is not disrupted.

FIG. 8 illustrates an exemplary circuit diagram of a RWC (reading/writing control circuit) of the semiconductor device 1 in accordance with the first exemplary embodiment. In FIG. 5, a RWC is shared between adjacent left-right MATs. Here, however, in order to simplify the explanation, a situation in which a RWC is connected to only the one side of the MAT will be explained. In FIG. 8, i denoted in GBL, GCS, sense amplifier circuit SA, data latch circuit LT, and YS represents a location of RWC (i-th from the bottom) in FIG. 6. As shown in FIG. 8, the RWC (44b-c etc.) includes a first writing circuit 81, a writing unit 111, a sense latch circuit (reading circuit) 84, and an input-output circuit 86. Here, the writing unit 111 includes a second writing circuit 82, a MAT writing control circuit 85.

FIG. 9 illustrates an example of the first writing circuit 81. Referring to FIG. 9, detailed configuration of the first writing circuit 81 will be described. As shown in FIG. 9, the first writing circuit 81 includes a first input terminal 201, a second input terminal 202, a first output terminal 301, a delay circuit 93, and a NOR logical circuit 94. The first input terminal 201 is connected to a third terminal 603 receiving the writing pulse signal (control signal) /WP. The second input terminal 202 is connected to one end of GBL_i. The first output terminal 301 is connected to one end of GCS_i. The delay circuit 93 includes a plurality of inverter circuits 112a-d connected in series. The second input terminal 202 is connected to one input node of the NOR logical circuit 94, and the first input terminal 201 is connected to the other input node of the NOR logical circuit 94 via the delay circuit 93. The first output terminal 301 is connected to an output node of NOR logical circuit 94.

According to the above configuration, during a MAT writing period, the writing pulse signal (control signal) /WP is controlled to be Low, so that the GBL is driven to VDD or VSS by the second writing circuit 82 in response to data of Q in the data latch circuit 88. In the first writing circuit 81, by providing the delay circuit 93, after the delay time corresponding to time period needed for the GBL to be driven to VDD or VSS, the GCS is driven by inverting the GBL potential.

Next, returning to FIG. 8, the MAT writing control circuit 85 will be described in detail. The MAT writing control circuit 85 includes a third input terminal 203, a fourth input terminal 204, a NAND logical circuit 95, and inverter circuits 96, 97. The third input terminal 203 is connected to one output node Q of the data latch circuit 88 latching write data. The fourth input terminal 204 is connected to the third terminal 603 receiving the writing pulse signal (control signal) /WP. The third input terminal 203 is connected to one input node of the NAND logical circuit 95 via the inverter circuit 96. The fourth input terminal 204 is connected to the other input node of the NAND logical circuit 95 via the inverter circuit 97. The NAND logical circuit 95 outputs a writing control signal C1. The MAT writing control circuit 85 supplies the writing control signal C1 to the second writing circuit 82.

According to the above configuration, in the MAT writing control circuit 85, if the writing pulse signal (control signal) /WP is controlled to be Low during a MAT writing time period, the writing control signal C1 becomes the same logical signal as Q of the data latch circuit 88 to be supplied to the second writing circuit 82.

Next, referring to FIG. 8, the second writing circuit 82 will be described in detail. The second writing circuit 82 includes a seventh input terminal 207, a second output terminal 302, PMOS transistors (102, 103), NMOS transistors (104, 105), and an inverter circuit 98. The seventh input terminal 207 is connected to the fourth terminal 604 receiving the reading pulse signal RP. The second output terminal 302 is connected to the other end of GBL_i. The PMOS transistors (102, 103) are connected in series between the power supply VDD and a node N13, and the NMOS transistors (104, 105) are connected in series between the node N13 and the ground. The node N13 is also connected to the second output terminal 302. The writing control signal C1 is supplied to gates of PMOS transistor 102 and NMOS transistor 105. The seventh input terminal 207 is connected to a gate of PMOS transistor 103, and connected to a gate of NMOS transistor 104 via the inverter circuit 98.

According to the above configuration, the reading pulse signal RP is controlled to be High level during a read operation, so that both PMOS transistor 103 and NMOS transistor 104 are in an off state in order that the second writing circuit 82 does not perform a write operation. On the other hand, if the reading pulse signal RP is at Low level, both PMOS transistor 103 and NMOS transistor 104 are in an on-state, the GBL_i is driven by both PMOS transistor 102 and NMOS transistor 105 connected above and below of PMOS transistor 103 and PMOS transistor 104 respectively in response to the writing control signal C1.

FIG. 10 illustrates an example of the sense latch circuit 84 in detail. Next, referring to FIG. 10, a configuration of the sense latch circuit 84 will be described in detail. As shown in FIG. 10, the sense latch circuit 84 includes a fifth input terminal 205, a sixth input terminal 206, first and second input-output terminals (401, 402), a sense amplifier circuit SA_i (87), a data latch circuit LT_i (88), and an NMOS transistor 101. The fifth input terminal 205 is connected to a fourth terminal 604 receiving the reading pulse signal RP. The sixth input terminal 206 is connected to the GBL_i via the second output terminal 302 (see FIG. 8). The first and the second input-output terminals (401, 402) are connected to the I/O line pair 89 via the input-output circuit 86 (the details will be described later).

The fifth input terminal 205 is connected to a gate of NMOS transistor 101. The input terminal 206 is connected to one of drain and source of the NMOS transistor 101, and the other of drain and source of the NMOS transistor 101 is connected to an input node of the sense amplifier circuit 87. The output node of sense amplifier circuit 87 is connected to the input node of the data latch circuit 88, and two output nodes Q, /Q being complementary from each other in the data latch circuit 88 are connected to the first and second input-output terminals (401, 402), respectively.

As shown in FIG. 10, the sense amplifier circuit 87 includes a reading current source 120, a differential amplifier circuit 114, a reference node 501, and switches 116, 118. One end of the reading current source 120 is connected to a power supply. A non-inverting input terminal of the differential amplifier circuit 114 is connected to one end of the NMOS transistor 101. An inverting input terminal of the differential amplifier circuit 114 is connected to a reference terminal 501. An output node of the differential amplifier circuit 114 is connected to the input node of data latch circuit 88 via the switch 118. The switch 116 is connected between the reading current source 120 and the non-inverting terminal of differential amplifier circuit 114. The switches 116, 118 are controlled to be conductive when the reading pulse signal RP is at High level.

According to the above configuration, if a memory cell is selected and the reading pulse signal RP is controlled to be High level during a read operation, the NMOS transistor 101 is in an on state, so that the input node of sense amplifier circuit 87 is electrically connected to the GBL_i. In the above state, a reading current flows into the selected memory from the reading current source 120 via the GBL_i and the selected LBL. The GBL_i potential varies in response to the resistive state of the selected memory cell. The differential amplifier circuit 114 compares the varied GBL_i potential and a reference voltage Vref supplied to the reference terminal 501, and the data latch circuit 88 latches read data depending on the magnitude relation of the compared result.

Next, referring to FIG. 10, the input-output circuit 86 will be described in detail. The input-output circuit 86 includes NMOS transistors 106, 107. Gates of the NMOS transistors 106, 107 are connected in common, and their connection node is connected to a terminal of selection signal YS_i. One terminals of source and drain of the NMOS transistors 106, 107 are connected to the input-output terminals 401, 402, respectively; the other terminals of source and drain of the NMOS transistors 106, 107 are connected to the lines of I/O line pair 89, respectively.

According to the above configuration, the data latch circuit 88 executes data input-output processing to and from external units by output nodes Q, /Q via the I/O line pair 89. Concretely, if the YS_i is controlled to be High level during a read operation, data latched by the data latch circuit LT_i (88) in the RWC selected by the YS_i is read out to the I/O line pair 89. And if the YS_i is controlled to be High level during a write operation, write data supplied via the I/O line pair 89 is written to the data larch circuit LT_i (88).

### Operation of the First Exemplary Embodiment

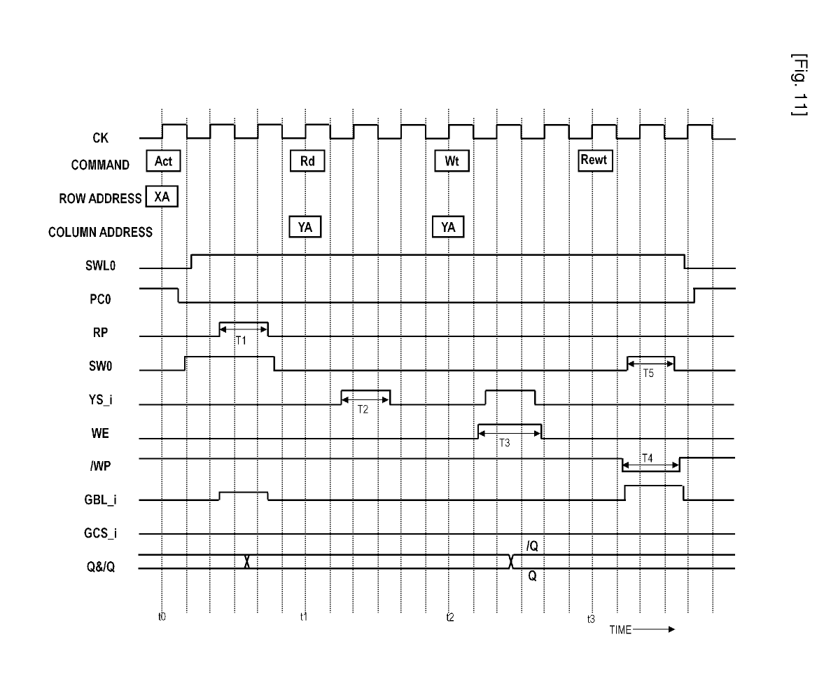

Next, referring to FIGS. 11 to 13, an operation of the semiconductor device 1 will be described in detail.

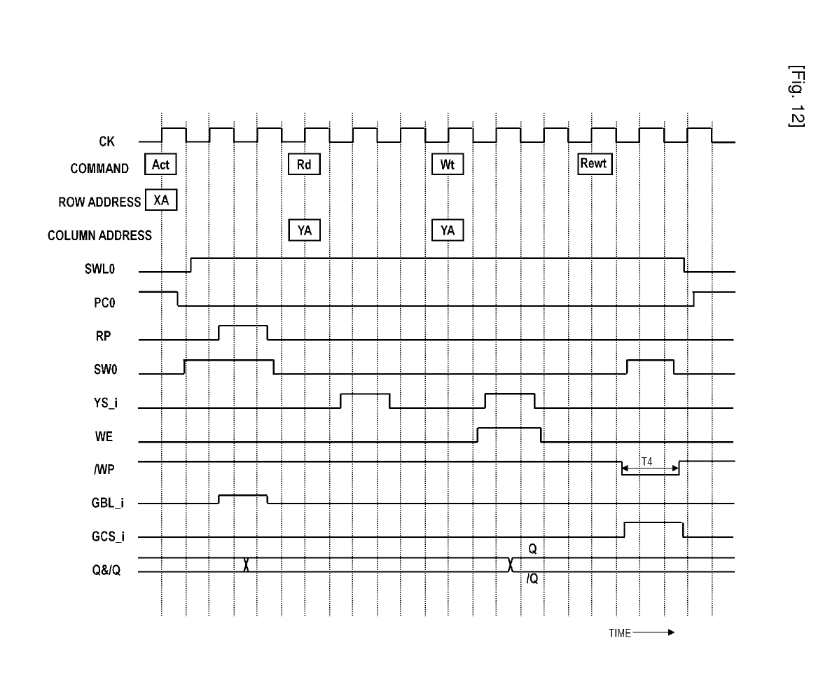

FIG. 11 illustrates an exemplary waveform chart showing an operation of flowing current in the direction of GBL to GCS (the operation is hereinafter referred to as “GBL->GCS write”). In this case, write data latched in the data latch circuit 88 is at Low level. In FIGS. 11 and 12, it is assumed that data of the selected memory cell is read out to be outputted to external units via the I/O line pair 89; after that, the read data is rewritten from the external unit to the data latch circuit 88 via the I/O line pair 89; and the selected memory cell is rewritten by the latched data. Here, FIG. 11 shows a situation where the rewrite operation corresponds to “GBL->GCS write” mentioned above.

In FIG. 11, first, a bank active command Act and a row address XA (including a bank address) are provided (timing t0 in FIG. 11). Next, in the MAT including a segment corresponding to the row address XA, a pre-charge signal PC0 and a connection signal SW0 corresponding to the selected local bit line LBL (for instance, LBL0 is assumed to be selected) are controlled to be Low level and High level (VPP potential), respectively. Next, a sub-word line SWL selected by the row address XA (for instance, SWL0 is assumed to be selected) is controlled to be High level (VPP potential). Next, if RP is controlled to be High level during a predetermined period (period T1 in FIG. 11), a reading current flows in the selected memory cell via the GBL_i and the LBL0; potential change of GBL_i is sense-amplified by the sense amplifier circuit SA_i (87) to be latched by the data latch circuit LT_i (88), so that data of Q and /Q are updated based on the read data; and after that, the SW0 is controlled to be VSS.

Next, if it is time for a page access period, a read command Rd and a column address YA (including a bank address) are provided (timing t1 in FIG. 11), the selection signal YS_i is controlled to be High during a predetermined period (period T2) in response to column address YA, so that data of Q and /Q are read out to the I/O line pair 89. Next, by updating only the column address YA, reading out by the page access is continued (the illustration is omitted in FIG. 11).

Next, if a write command Wt and a column address YA (including a bank address) are provided (timing t2 in FIG. 11), a write enable signal WE is controlled to be High level during a predetermined period (period T3 in FIG. 11); the YS_i is controlled to be High level during a predetermined period; data of Q and /Q are written to the data latch circuit LT_i (88) from the I/O line pair 89. Next, writing to the data latch circuit by the page access is continued by updating the column address YA (the illustration is omitted in FIG. 11).

Lastly, if a rewrite command Rewt is provided (timing t3 in FIG. 11), a rewrite operation is started. When /WP is controlled to Low level during a predetermined period (period T4 in FIG. 11), GBL_i and GCS_i are controlled to be High level and Low level, respectively, in response to Low level of Q of the data latch circuit LT_i (88). And next, the SW0 is controlled to be High level during a predetermined period (period T5 in FIG. 11), so that data is written to the memory cell in the MAT. After that, the SWL0 is controlled to be Low level, and next, PC0 is controlled to be High level, so that a series of operations are completed.

Meanwhile, FIG. 11 illustrates a situation in which the rewrite command Rewt is provided from an external unit. However, the present invention is not limited to the situation. For instance, after a read or write operation, a rewrite command may be issued automatically in the semiconductor device by a read command associated with a rewrite operation or a write command associated with a rewrite operation. In this case, a similar operation as in FIG. 11 is performed.

FIG. 12 illustrates an exemplary waveform chart showing an operation of flowing in the direction from GCS to GBL (it is hereinafter referred to as “GCS->GBL write”). In this case, write data latched in the data latch circuit 88 is High level. A difference of FIG. 12 from FIG. 11 resides only in that the GBL_i and the GCS_i are driven to Low level and High level, respectively in response to High level of Q during a rewrite operation (period T4 in FIG. 12). Since other part of the operation is similar to that in FIG. 11, the explanation will be omitted.

FIG. 13 illustrates an exemplary operational waveform of each of the signals associated with FIGS. 11, 12 in which SWL0 and LBL0 are selected in a sub-MAT (63 etc. in FIG. 7) of activated segment. The left side (A) of FIG. 13 shows: data read out in response to an active command->page access period->rewrite operation by “GBL->GCS write” in response to a rewrite command.

First, during a pre-charge period, an inverting segment selection signal /SEL and pre-charge signals PC0 to PCk−1 are controlled to be VPP; a segment selection signal SEL, connection signals SW0 to SWk−1, and sub-word lines SWL0 to SWLm−1 are controlled to be VSS. The local bit line LBL0 and the local common source line LCS are pre-charged to VSS. The GBL and the GCS are also pre-charged to VSS by a RWC.

Next, during a cell selection period, /SEL and PC0 are controlled to be VSS, and SEL, SW0 and SWL0 are controlled to be VPP, so that the LBL0 and the LCS are electrically connected to the GBL and the GCS, respectively.

Next, just before start of a sense latch period, a reading current Tread flows in the selected memory cell via the GBL and LBL0. During the sense latch period, a GBL potential is compared to a reference voltage Vref, and the potential difference between them is sense-amplified by the sense amplifier circuit 87 to be latched as read data in the data latch circuit 88. During the above sense latch period, the GCS and LCS potentials are held at VSS, and the GBL and LBL0 potentials are held at Vread.

When the sense latch period is completed, the GBL and LBL0 are returned to VSS. Next, the SW0 is controlled to VSS, so that the LBL0 is disconnected from the GBL to be held at VSS via the selected memory cell. Next, a page access period is started. During the page access period, data is read out from the data latch circuit 88 in response to a read command, and the data is written to the data latch circuit 88 in response to a write command. Here, the write data may be provided from an external unit, or error-corrected data which has been checked by an error correction circuit. Since the page access is performed to only the data latch circuit 88, the GBL and GCS are held to VSS during the page access period, so that the state of each of the signals in the sub-MAT is held.

Next, when a rewrite command is provided, a MAT writing period (it is also hereinafter referred to as “rewriting period”) is started. First, the GBL and LBL0 are driven to VDD, and the GCS and LCS are driven to VSS, in response to data write operation by the GBL->GCS write. Next, SW0 is controlled to VPP during a predetermined period (corresponding to the writing period), so the LBL0 is connected to the GBL again and the write data is written to the memory cell in the MAT.

After that, during a de-selection period, the SWL0 and the SEL are controlled to be VSS. Next, during a pre-charge period, /SEL and PC0 are controlled to be VPP, so that the LCS and LBL0 are controlled to be VSS and pre-charged to VSS. The GCS and GBL are pre-charged to VSS by a RWC.

Next, the right side (B) of FIG. 13 shows: data readout->page access period->a rewrite operation by “GCS->GBL” write in response to a rewrite command. Here, operations from the pre-charge period to the page access period are similar to the left side (A) of FIG. 13, so the explanation will be omitted.

When a rewrite command is received, a rewriting period is started. First, in response to data writing by GCS->GBL write, the GBL and LBL0 are driven to VSS, and the GCS and LCS are driven to VSS. Next, SW0 is controlled to be VPP during a predetermined period (corresponding to writing period), so that the LBL0 is connected to the GBL again, and the write data is written to the memory cell of the MAT. Operations from a de-selection period to a pre-charge period after the above operation are similar to those in (A) of FIG. 13, so that the overlapping explanation will be omitted.

Meanwhile, in the explanation of operation in the first exemplary embodiment above, a situation in which a memory cell corresponding to the SWL0 and LBL0 are selected among m*k memory cells in the sub-MAT was explained. However, an operation in which other memory cell is selected is similar.

An effect of the first exemplary embodiment will be described below. According to the semiconductor device 1 of the first exemplary embodiment, it is possible that the length resulting by adding the length of GBL and the length of GCS on a writing current path is nearly constant, regardless of the position of a memory cell accessed among memory cells in a MAT. This is because a sum of length L1 and length L2 of FIG. 9 is nearly constant regardless of the position of a selected sub-MAT as mentioned above in FIG. 9. Therefore, if the sheet resistance of the bit line BL is set to be equal to that of the source line SL by selecting material properties, thicknesses, and line widths of lines of the bit line BL and the source line SL, it is possible for parasitic resistance value on the writing current path to be nearly constant. As the result, in case where a constant voltage drive typed writing circuit is adopted as in the semiconductor device 1 of the first exemplary embodiment, an effect of improving a writing margin is brought about. Alternatively, in case where a constant current drive typed writing circuit is adopted, an effect is brought about that a power supply voltage can be reduced.

According to the semiconductor device 1 of the first exemplary embodiment, when a rewriting is performed to a memory cell, a logical signal generated based on the data outputted by the latch in FIG. 9 is transmitted to the first writing circuit 81 via the global bit line GBL. The first writing circuit 81 controls the first line to be High (for instance, a power supply potential) or Low (for instance, ground potential) based on the logical level of the logical signal. It becomes possible that a logical signal determined based on the latched data is not transmitted via a signal line routed in the peripheral area of the memory array but via the global bit line GBL. As the result, the signal line routed in the peripheral area of the memory array is not needed, so that an effect of reducing layout area is brought about.

Besides, in case where a bit line and a source line are hierarchically structured as in the semiconductor device 1 of the first exemplary embodiment, it is possible that the lengths of a local bit line LBL and a local common source line LCS at the lower hierarchy are set to be short by adopting the hierarchical structure, and further the pitches of the global bit line GBL and the global common source line GCS at the higher hierarchy can be reduced. Thus, since it becomes possible to use lower resistance lines for the global bit line GBL and the global common source line GCS, parasitic resistance of bit line and source line can be reduced as a whole, which makes it possible to enhance the above effects.

Since by adopting the constitution capable of executing page access, a write operation is performed only for the data latch circuit during the page access period for the open page, an effect is brought about that even if a variable resistance memory cell with a long writing time is used, the cycle time of column access is not increased.

The area of a reading/writing control circuit RWC becomes large compared to a sense amplifier in such as DRAM. However, as shown in FIG. 7, it is possible to widen the line pitches of GBL and GCS to several times to dozens of times of the line pitch of LBL. So, it is also possible to widen the arrangement pitch of RWCs connected to the GBL and GCS compared to those in DRAM. As the result, since it is possible to layout RWCs easily and also reduce the number of RWCs, an effect is brought about that the increase of chip area can be suppressed.

Meanwhile, in the semiconductor device 1 in accordance with the first exemplary embodiment, a situation in which the bit lines and the source lines have hierarchical structure was explained. However, the present invention is not limited to the above constitution, and the present invention can be applied to bit lines and source lines which do not have hierarchical structure. In this case, it is only necessary that the sub-word line SWL is controlled similarly as the connection signal SW.

### Variant of First Exemplary Embodiment

Next, a variant of the first exemplary embodiment will be described. In the variant of first exemplary embodiment, a control of the connection signal SW0 is changed from that in the first exemplary embodiment. Regarding the other points, the variant of first exemplary embodiment is identical to the first exemplary embodiment. So, the changed point will be explained mainly below.

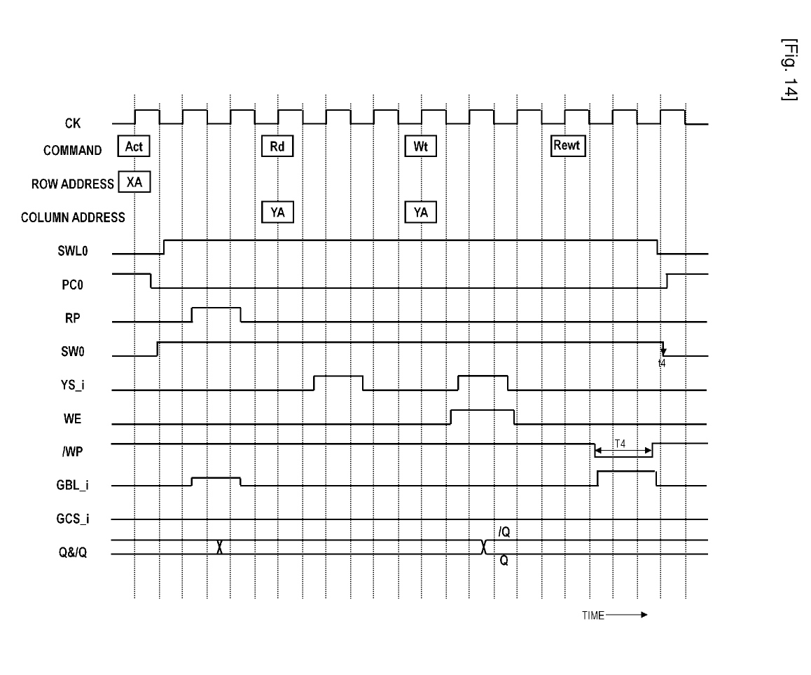

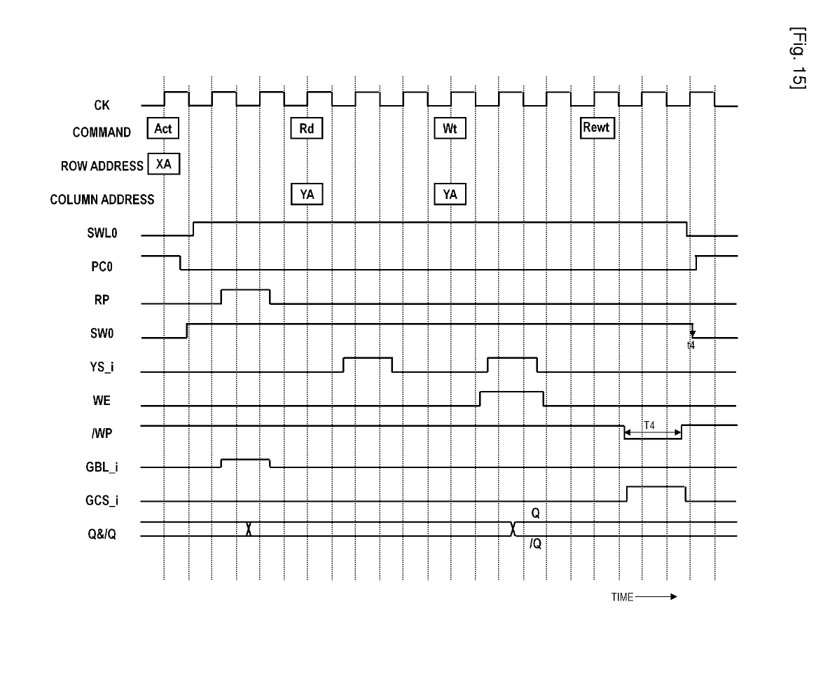

FIG. 14 illustrates an exemplary operational waveform of GBL->GCS write in accordance with the variant of first exemplary embodiment. FIG. 15 illustrates an exemplary operational waveform of GCS->GBL write in accordance with the variant of first exemplary embodiment. As can be seen by comparing FIGS. 14, 15 to FIGS. 11, 12, respectively, even after data of Q and /Q are read out, the SW0 is held to High level (VPP) in FIGS. 14, 15; after a rewrite operation is completed, the SW0 is controlled to VSS (timing t4 in FIGS. 14, 15). As other difference of FIGS. 14, 15 from FIGS. 11, 12, a rewriting period is determined by a pulse width of SW0 in FIGS. 11, 12, whereas the rewriting period is determined by a pulse width of the writing pulse signal (control signal) /WP (corresponding to a period T4 of FIGS. 14, 15). By controlling as mentioned above, it is possible to reduce the number of driving SW0 by one time, so that an effect of reducing power consumption is brought about.

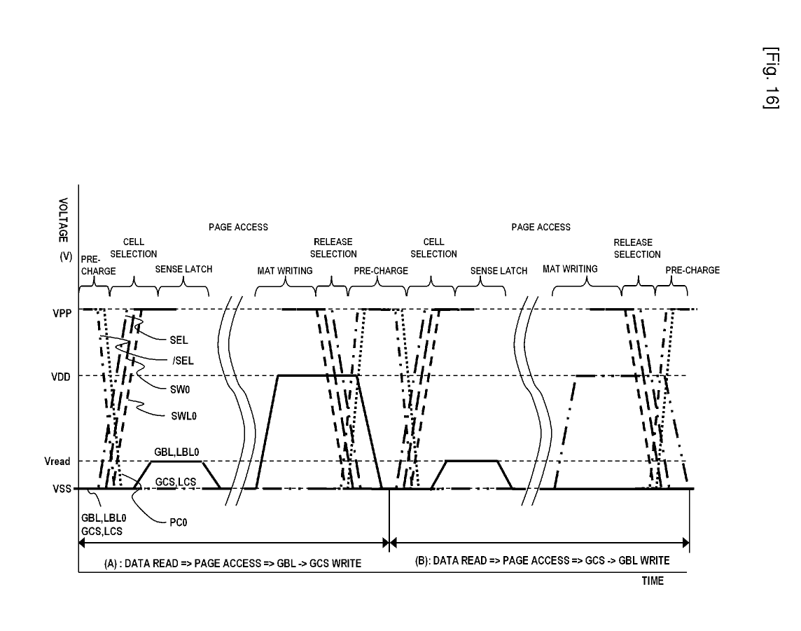

FIG. 16 illustrates an exemplary operational waveform of each of the signals in a sub-MAT (63 etc. in FIG. 7) of activated segment in which the SWL0 and LBL0 are selected associated with FIGS. 14, 15. As can be seen by comparing FIG. 16 to FIG. 13, a difference of FIG. 16 from FIG. 13 resides only in that even after data is read out, the SW0 is maintained at the VPP; and after the rewrite operation is completed, the SW0 is controlled to VSS. Other than the above point, FIG. 16 is identical to FIG. 13, so the overlapping explanation will be omitted.

Meanwhile, a control method in accordance with the variant of first exemplary embodiment can be applied without change to a memory cell array in which bit lines and source lines do not have hierarchical structure.

As mentioned above, according to the variant first exemplary embodiment, similar effects as in the first exemplary embodiment are brought about. Further, since the number of driving the SW0 can be reduced by one time, an effect of reducing power consumption can be brought about than in the first exemplary embodiment.

### Second Exemplary Embodiment

Next, a second exemplary embodiment will be described.

FIGS. 17, 18 illustrate an exemplary circuit diagram of a RWC of a semiconductor device in accordance with the second exemplary embodiment. A difference of the second exemplary embodiment from the first exemplary embodiment resides in that in the second exemplary embodiment, a rewrite operation is performed only for memory cells corresponding to latches in which writing to the data latch circuit 88 (writing by a write command Wt) has been performed. Comparing FIG. 17 and FIG. 8 (first exemplary embodiment), only the configuration of MAT writing control circuit 170 is different. Comparing FIG. 18 and FIG. 9 (first exemplary embodiment), only the configuration of the first writing circuit 180 is different. Therefore, the MAT writing control circuit 170 and the first writing circuit 180 different from the first exemplary embodiment will be described, however, other constituent components are denoted by the same reference symbols and their overlapping explanation will be omitted.

First, referring to FIG. 17, a configuration of the MAT writing control circuit 170 will be described in detail. The MAT writing control circuit 170 includes a third input terminal 203, a fourth input terminal 204, a first control unit 171, and a second control unit 172. Here, since the third input terminal 203 and the fourth input terminal 204 are identical to the first exemplary embodiment, the explanations will be omitted.

The first control unit 171 includes PMOS transistors (160, 162), NMOS transistors (161, 163, 164), and an inverter circuit 178. The PMOS transistor 162, the NMOS transistor 162, and the NMOS transistor 164 are connected in series between the power supply VDD and the ground. Here, a first rewrite node NO is a node to which a drain of PMOS transistor 162 and a drain of NMOS transistor 163 are connected, and the first rewrite node NO is also connected to an input node of a NOR logical circuit 175 of the second control unit. The pre-charge signal /PC is supplied to a gate of the PMOS transistor 162. The selection signal YS_i is supplied to a gate of the NMOS transistor 163. The write enable signal WE is supplied to a gate of the NMOS transistor 164. According to the above configuration, the first rewrite node NO potential is pre-charged to the potential VDD in advance by controlling /PC to be Low level; and further, when both YS_i and WE transit to High level, the first rewrite node NO potential transits to VSS (ground potential).

The PMOS transistor 160 and the NMOS transistor 161 are connected in series between the power supply VDD and the ground, which constitute an inverter circuit. The above inverter circuit is connected to the inverter circuit 178, which constitutes a latch circuit. The drain of PMOS transistor 160, the drain of NMOS transistor 161, and the input node of the inverter circuit 178 are connected in common to the first rewrite node NO. According to the above configuration, the first rewrite node NO potential controlled by /PC, YS_i, and WE is held by the latch circuit.

The second control unit 172 includes three NOR logical circuits 173, 174, 175, and a delay circuit 176. One input node of the NOR logical circuit 175 is connected to the first rewrite node NO. The other input node of the NOR logical circuit 175 is connected to the output node of inverter circuit 178 of the first control unit 171 via the delay circuit 176. Three input nodes of NOR logical circuit 174 are connected to the third input terminal 203 (signal of Q of the data latch circuit 88), the first rewrite node NO, and the fourth input terminal (signal of /WP), respectively. One input node of NOR logical circuit 173 is connected to the output node of NOR logical circuit 174; the other input node of NOR logical circuit 173 is connected to the output node of NOR logical circuit 175.

According to the above configuration, the second control unit 172 generates a writing control signal C2 based on the signal of Q of the data latch circuit 88, the first rewrite node NO potential, and /WP to supply the writing control signal C2 to the second writing circuit 82. Concretely, if the first rewrite node NO potential transits from VDD to VSS in the first control unit 171, the NOR logical circuit 175 outputs a pulse signal with a pulse width corresponding to a delay time of the delay circuit 176. Since /WP is High level during other than the rewriting period, the output of the NOR logical circuit 174 is Low level, so that the above-mentioned pulse signal generated by the NOR logical circuit 175 is inverted by the NOR logical circuit 173 to become the writing control signal C2. Then, the GBL_i is driven by the writing control signal C2. At this time, the pulse signal is inverted again. As the result, the signal with the pulse width corresponding to the delay time of the delay circuit 176 generated by the NOR logical circuit 175 is transferred to the GBL_i, and further transmitted to the second input terminal 202 of first writing circuit 180 via the GBL_i. After generating the above pulse signal, the NOR logical circuit 175 outputs Low level, so that the NOR logical circuit 173 and the NOR logical circuit 174 operate similarly as in the MAT writing control circuit of the first exemplary embodiment.

Next, referring to FIG. 18, the first writing circuit will be described in detail. The first writing circuit 180 includes a first input terminal 201, a second input terminal 202, a first output terminal 301, a third control unit 183, and a fourth control unit 184. The first input terminal 201, the second input terminal 202, and the first output terminal 301 are identical to those in the first exemplary embodiment, so the explanations will be omitted.

The third control unit 183 includes PMOS transistors 185, 188, NMOS transistors 186, 189, and an inverter circuit 187. The PMOS transistor 188 and the NMOS transistor 189 are connected in series between the power supply VDD and the ground. Here, a second rewrite node N1 is a node to which a drain of PMOS transistor 188 and a drain of NMOS transistor 189 are connected, and also a node to which a drain of PMOS transistor 185 and a drain of NMOS transistor 186 are connected, and further a node connected to an input node of inverter circuit 187. The pre-charge signal /PC is supplied to a gate of PMOS transistor 188. The gate of NMOS transistor 189 is connected to the second input terminal 202. According to the above configuration, the second rewrite node N1 potential is pre-charged to the potential VDD in advance by controlling /PC to be Low level. After that, if the pulse signal (pulse signal generated by the NOR circuit 175 of the second control unit 172) transmitted from the second input terminal 202 via the GBL_i transits to High level, the NMOS transistor 189 turns on by receiving the High level, so that the second rewrite node N1 potential transits to VSS.

The PMOS transistor 185 and the NMOS transistor 186 constitute an inverter circuit, and this inverter circuit and inverter circuit 187 are connected, which constitutes a latch circuit. A drain of PMOS transistor 185, a drain of NMOS transistor 186, and an input node of inverter circuit 187 are connected in common to the second rewrite node N1. According to the above configuration, the second rewrite node N1 potential which is controlled by /PC and the signal transmitted via the GBL_i is held by the above latch circuit.

The fourth control unit 184 includes a NOR logical circuit 190, and a delay circuit 191. The first input terminal 201 is connected to an input node of the delay circuit 191. Three input nodes of the NOR logical circuit 190 are connected to the second input terminal 202, the second rewrite node N1, and an output node of the delay circuit 191, respectively. Concretely, the delay circuit 191 includes a plurality of inverter circuits similarly as in the delay circuit (93 in FIG. 9) of the first exemplary embodiment. As can be seen by comparing the fourth control unit 184 to the first writing circuit (81 in FIG. 9) of the first exemplary embodiment, an input of the second rewrite node N1 is newly added to the NOR circuit 190 of the fourth control unit 184.

According to the above configuration, if /WP is controlled to be Low level by receiving a rewrite command Rewt in the state where the first rewrite node NO and the second rewrite node N1 are set to be Low level, writing to a memory cell is performed in response to data of Q of the data latch circuit 88 similarly as in the first exemplary embodiment. On the other hand, the first rewrite node NO and the second rewrite node N1 corresponding to the data latch circuit 88 in which writing has not been performed during an operation by a write command Wt are held at High level. So, even if the /WP is controlled to Low level during a predetermined period by receiving a rewrite command Rewt, writing to the memory cell is not performed.

Meanwhile, in the second exemplary embodiment, the GBL is driven to High level during a predetermined period if writing to the data latch circuit 88 occurs during a page access period. Thus, in a case where the second exemplary embodiment is applied to a memory cell array without hierarchical structure of the bit line, the selected SWL is controlled to be Low level once during the page access period in order not to miss-write to the memory cell, and when a rewriting period is started in response to the rewrite command Rewt, the SWL0 may be controlled to be High level again. The writing period can be determined by the overlapping portion of pulse widths of the SWL0 and /WP.

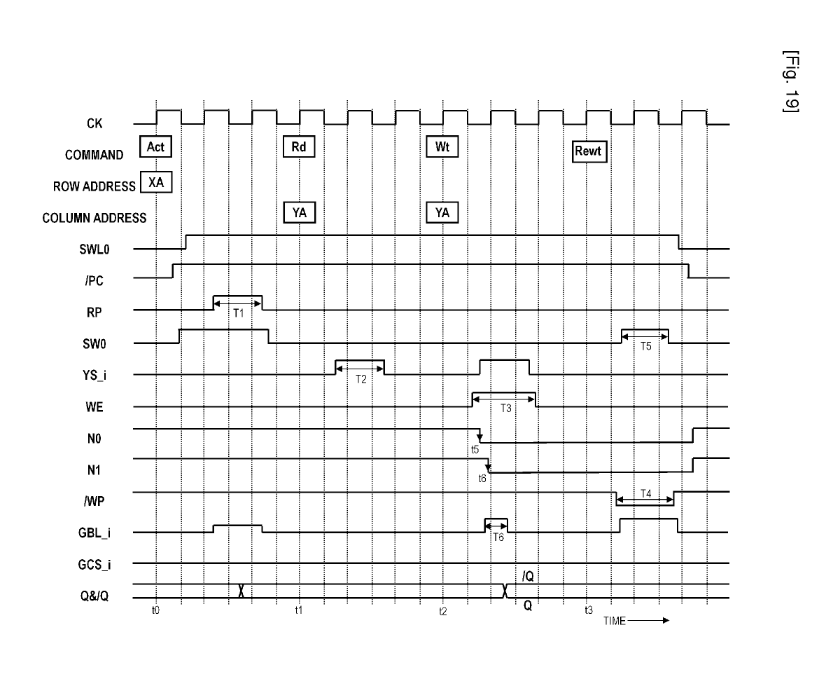

FIG. 19 illustrates an exemplary operational waveform of GBL->GCS write in the second exemplary embodiment. If a bank active command Act and a row address XA (including a bank address) are provided (timing t0 in FIG. 19), /PC is controlled to be High level; PC0 corresponding to selected LBL in the MAT including a segment corresponding to XA is controlled to Low level (not shown), and the SW0 is controlled to be High level; and next, the SWL0 selected by XA is controlled to High level (VPP). Next, if RP is controlled to be High level during a predetermined period (period T1 in FIG. 19), reading current Tread flows via the GBL_i and LBL0. The GBL_i potential at this time is sensed and latched. And Data of Q and /Q of the data latch circuit 88 are updated based on the read data which has been sensed and latched, and then the SW0 is controlled to be VSS.

Next, when the page access period is started, and a read command Rd and a column address YA (including a bank address) are provided (timing t1 in FIG. 19), YS_i corresponding to the YA is controlled to High level during a predetermined period (period T2 in FIG. 19), so that data of Q and /Q are read out to the I/O line pair 89. Next, when a write command Wt and YA are provided (timing t2 in FIG. 19), WE is controlled to be High level during a predetermined period (T3 in FIG. 19), and YS_i is controlled to be High during a predetermined period, so that the NO transits to Low level (timing t5 in FIG. 19). As the result, the GBL_i is controlled to be High level during a predetermined period (period T6 in FIG. 19), so that the N1 transits to Low level (timing t6 in FIG. 19). And data of Q and /Q are written to the data latch circuit 88 via the I/O line pair 89.

Lastly, when a rewrite command Rewt is provided (timing t3 in FIG. 19), a rewrite operation is started; when /WP is controlled to be Low level during a predetermined period (period T4 in FIG. 19), the GBL_i, the GCS_i are controlled to be High level, Low level, respectively; and next, the SW0 is controlled to be High during a predetermined period (period T5 in FIG. 19), so that the data is written to the memory cell in the MAT. After that, the SWL0 is controlled to be Low level, and next the PC0 is controlled to be High level (not shown), whereupon a series of page access operations are completed.

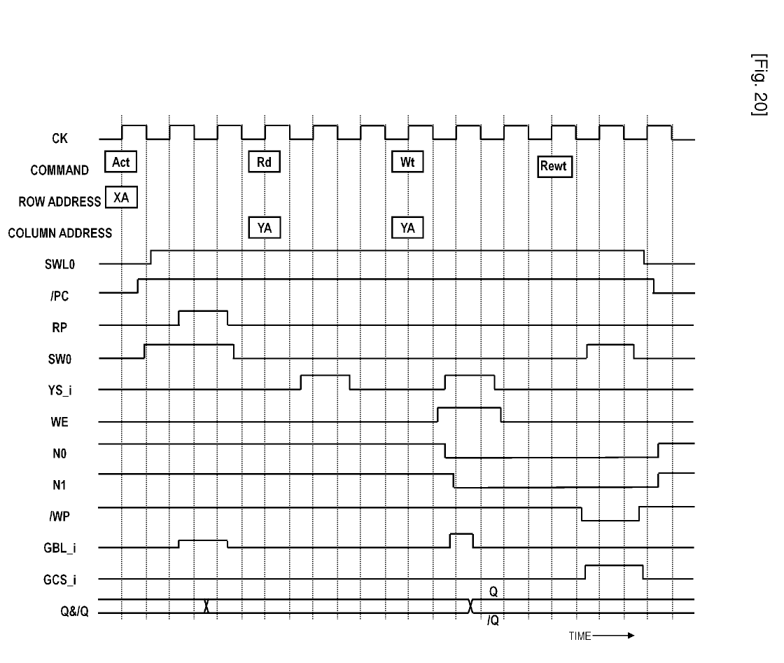

FIG. 20 illustrates an exemplary operational waveform of GCS->GBL write in the second exemplary embodiment. A different portion of FIG. 20 from FIG. 19 resides in that the GBL_i and the GCS_i are driven to Low level, High level, respectively, corresponding to High level of Q in the data latch circuit 88 during a rewrite operation (period T4 in FIG. 20). Since other portions in FIG. 20 are the same as in FIG. 19, overlapping explanation will be omitted.

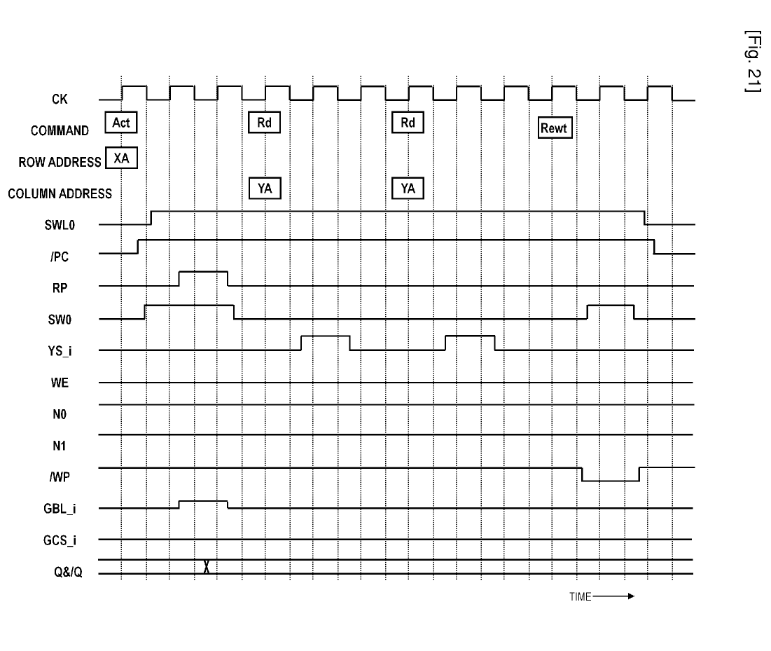

FIG. 21 illustrates an exemplary operational waveform for the data latch circuit 88 in which writing is not performed during the page access period in the second exemplary embodiment. A Difference of FIG. 21 from FIGS. 19, 20 reside in that since the write enable signal WE does not transit to High level during the page access period, the first rewrite node NO and the second rewrite node N1 are held to High. As the result, even if /WP is driven to Low level during a predetermined period in the rewriting period, both GBL_i and GCS_i are still VSS, so that writing to the memory cell does not occur.

Even if writing occurs in other data latch circuit(s) during the page access period, the YS_i is not controlled to High level in the data latch circuit which has not been selected by the column address YA, so the first rewrite node NO and the second rewrite node N1 are held to High level. Therefore, writing (rewriting) is not performed to the memory cell corresponding to the data latch circuit which has not been selected by the column address YA during the writing period by a write command Wt.

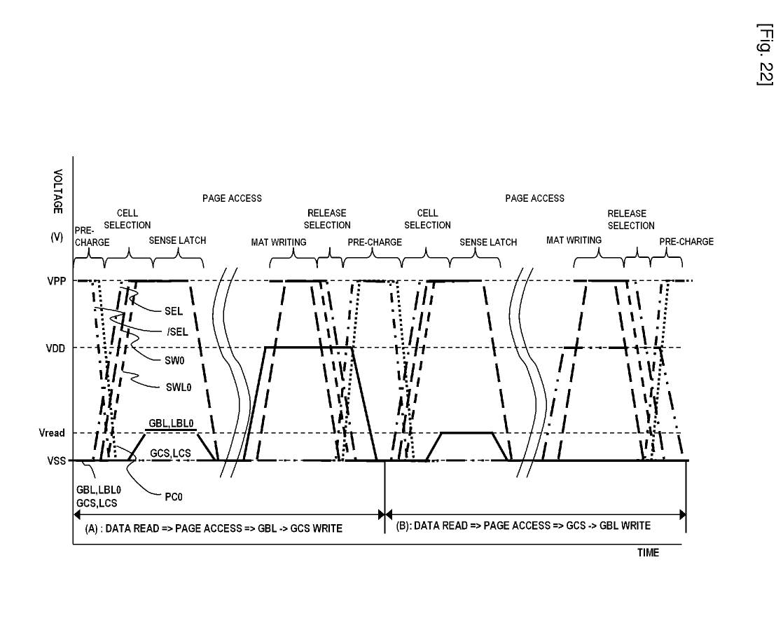

FIG. 22 illustrates an exemplary operational waveform of each of the signals in which the SWL0 and LBL0 are selected in a sub-MAT (63 in FIG. 7) of a selected segment in the second exemplary embodiment. In the second exemplary embodiment, for a memory cell corresponding to the data latch circuit in which writing has been performed during the page access period, similar operation as in the first exemplary embodiment is performed as mentioned above. So, the operational waveforms in FIG. 22 are identical to those in FIG. 13 (first exemplary embodiment). So, the overlapping explanation will be omitted. Meanwhile, in the second exemplary embodiment, writing period can be determined by the overlapping portion of pulse widths of SW0 and /WP.

Meanwhile, in the explanation of operation in the second exemplary embodiment, a case where a memory cell corresponding to the SWL0 and LBL0 is selected among m*k memory cells in the sub-MAT was described. However, an operation in which other memory cells are selected is similar to that in the above case.

An effect according to the second exemplary embodiment will be described below. In the second exemplary embodiment, all the data which has been read out is not rewritten, but writing (rewriting) operation is performed to only a memory cell which is written from external units of the semiconductor device or a memory cell which has been error-corrected. As the result, an effect of reducing consumption current during the rewriting period is brought about in addition to the effects obtained in the first exemplary embodiment.

In case where page mode operation is adopted as in DRAM, it is possible to perform a rewrite operation to only a memory cell(s) which is written from an external unit. Also in the above case, an effect of reducing consumption current during the rewriting period is brought about.

The global bit line GBL is used for transmitting information of whether rewriting to the memory cell is performed or not from the MAT writing control circuit 170 to the first writing circuit 180 disposed at the opposite side of the MAT writing control circuit 170. It is unnecessary to separately arrange a line(s) for transmitting the information, so that an effect of achieving the semiconductor device by a configuration of smaller scale is brought about.

### Third Exemplary Embodiment

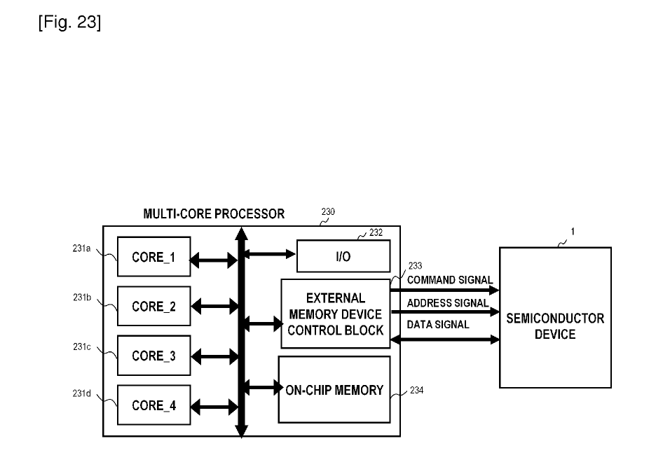

Next, referring to FIG. 23, a third exemplary embodiment will be described.

FIG. 23 illustrates an exemplary information processing system in accordance with the third exemplary embodiment. In the third exemplary embodiment, an information processing system including the semiconductor device 1 according to each of the exemplary embodiments mentioned above and a multi-core processor 230 is configured. As shown in FIG. 23, the multi-core processor 230 includes core_1 to core_4 (231a-d), an I/O 232, an external memory device control block 233, and an on-chip memory 234. The external memory device control block 233 controls the semiconductor device 1 by exchanging a command signal, an address signal, and a data signal with the semiconductor device 1.

According to the information processing system in accordance with the third exemplary embodiment, it is possible to provide a main memory using variable resistance memory cells with high-capacity, high-reliability, and low consumption current to the multi-core processor 230.

Even if variable resistance memory cells with a relatively long writing time are used, it is possible to shorten the column access cycle time using the page access operation, and it is further possible to conceal the increased time for adding a rewriting period by accessing multi-banks in interleave, which makes it possible to secure a data bandwidth of main memory bus enough to maintain the performance of multi-core processor.

Meanwhile, in the semiconductor device disclosed in each of the exemplary embodiments, a case using a STT-RAM was described. However, the present invention is not limited to the case. For instance, the disclosure in each of the exemplary embodiments can be applied to a semiconductor device using a Re-RAM (Resistive Random Access Memory) using metal oxides or a PCM (Phase Change Memory) as well.

The present invention can be applied to a semiconductor memory device using bipolar typed variable resistance memory cells.

The exemplary embodiments and examples may include variations and modifications without departing the gist and scope of the present invention as disclosed herein and claimed as appended herewith, and furthermore based on the fundamental technical spirit. It should be noted that any combination and/or selection of the disclosed elements may fall within the claims of the present invention. That is, it should be noted that the present invention of course includes various variations and modifications that could be made by those skilled in the art according to the overall disclosures including claims and technical spirit. Particularly, any numerical range disclosed herein should be interpreted that any intermediate values or subranges falling within the disclosed range are also concretely disclosed even without specific recital thereof.

### REFERENCE SIGNS LIST

1, 9 semiconductor device
2a-h memory cell array (bank_0-7)
3a-d array_0-3
5a-h BLOCK_0-7
11 column decoder
12 array control circuit
13 MWL (main word line) decoder
14 RW (read write) amplifier
15 latch circuit
16 data input-output buffer
17 column address buffer
18 bank and row address buffer
19 mode register
20 chip control circuit
21 command decoder
22 clock generation circuit
23, 88 data latch circuit
24, 87 sense amplifier circuit
25a-c, 75a-f variable resistance element
26a-c, 27, 30, 76a-f, 77, 78, 101, 104, 105, 106, 107, 161, 163, 164, 186, 189 NMOS transistor
28, 29, 102, 103, 160, 162, 185, 188 PMOS transistor
31, 33, 81, 180 first writing circuit
32, 34, 82 second writing circuit
35a-c, 68a-f first terminal
36a-c, 69a-f second terminal
37a-c, 67a-f memory cell (variable resistance memory cell)
43 MAT
44a-c RWC (reading/writing control circuit)
45a-c SWL (sub word line) driver
46a-c sub-MAT control circuit
51a-b activated RWC column
52 activated segment
63 sub-MAT
71 LCS (local common source line) control circuit
72 LBL (local bit line) pre-charge circuit
73 memory cell array
74 LBL (local bit line) selection circuit
79a-c pre-charge NMOS transistor
80a-c connection NMOS transistor
83 MAT area
84 sense latch circuit (reading circuit)
85 MAT writing control circuit (writing control circuit)
86 input-output circuit
89 I/O line pair
93, 176, 191 delay circuit
94, 173, 174, 175, 190 NOR logical circuit
95 NAND logical circuit
96, 97, 98, 112a-d, 178 inverter circuit
111 writing unit
114 differential amplifier circuit
116, 118 switch
120 reading current source (reading current circuit)
171 first control unit
172 second control unit
183 third control unit
184 fourth control unit
201, 202, 203, 204, 205, 206, 207 input terminal
230 multi-core processor
231a-d core_1-4
232 I/O
233 external memory device control block
234 on-chip memory
301, 302 output terminal
401, 402 input-output terminal
501 reference terminal
601, 602, N11, N12, N13 node
603 third terminal
604 fourth terminal
DQ data input-output terminal
SL source line (first line)
BL bit line (second line)
GCS, GCS_i global common source line
GBL, GBL_i global bit line
LCS local common source line
LBL, LBL0-LBLk−1 local bit line
SEL segment selection signal
/SEL reversed segment selection signal
PC0-PCk−1 pre-charge signal
SWL0-SWLm−1 sub word line
SW0-SWk−1 connection signal
MC memory cell (variable resistance memory cell)
YS_i selection signal
Vref reference voltage
N0 first rewrite node
N1 second rewrite node
/PC pre-charge signal
C1, C2 writing control signal
/WP writing pulse signal
RP reading pulse signal

1. A semiconductor device comprising:
a memory cell array including a first memory cell connected between a first terminal and a second terminal, written to a first resistive state by applying a voltage in a first direction to the first memory cell, and written to a second resistive state by applying a voltage in a second direction different from the first direction to the first memory cell;
a first line and a second line connected to the first terminal and the second terminal, respectively;
a third terminal receiving a control signal; and
a first writing circuit comprising a first input terminal connected to the third terminal, a second input terminal connected to one end of the second line, and a first output terminal connected to one end of the first line, and
the first writing circuit being configured to control the first line based on the control signal of the first input terminal and a signal of the second input terminal transmitted via the second line.

2. The semiconductor device according to claim 1, wherein
when the control signal is active, the first writing circuit inverts a first potential of the second line to output an inverted one of the first potential as a potential of the first output terminal.

3. The semiconductor device according to claim 1, further comprising:
a writing unit comprising a third input terminal receiving write data, a fourth input terminal receiving the control signal, and a second output terminal connected to the other end of the second line, and
the writing unit being configured to control the second line based on the write data of the third input terminal and the control signal of the fourth input terminal.

4. The semiconductor device according to claim 3, further comprising: a pair of I/O lines; and
a reading circuit comprising first and second input-output terminals connected respectively to the I/O lines and reading out data from the second line, and the first input-output terminal of the reading circuit being connected to the third input terminal of the writing unit so that the writing unit receives write data from the first input-output terminal of the reading circuit.

5. The semiconductor device according to claim 4, wherein
the write data, which the writing unit receives from the first input-output terminal of the reading circuit, is data which has been read out from the first memory cell.

6. The semiconductor device according to claim 4, further comprising:
a fourth terminal receiving a read control signal, wherein the reading circuit comprises:
a fifth input terminal connected to the fourth terminal;
a sixth input terminal connected to the second line and the second output terminal of the writing unit;
a sense amplifier circuit including an input node and an output node; a first transistor including a gate connected to the fifth input terminal and a source-drain path connected between the input node of sense amplifier circuit and the sixth input terminal; and
a data latch circuit including an input terminal connected to the output node of sense amplifier circuit, and two output nodes being complementary from each other and connected respectively to the first and the second input-output terminals.

7. The semiconductor device according to any one of claims 3, wherein
the first and the second lines are arranged parallel to each other on the memory cell array and extend over the memory cell array,
the one end of the first line and the other end of the first line are arranged on opposite sides of the memory cell array from each other, and
the one end of the second line and the other end of the second line are arranged on opposite sides of the memory cell array from each other.

8. The semiconductor device according to claim 6, wherein
the writing unit comprises:
a seventh input terminal connected to the fourth terminal;
a writing control circuit producing a writing control signal based on the write data of the third input terminal and control signal of the fourth input terminal; and
a second writing circuit being configured to control the second line based on the reading pulse signal of the seventh input terminal and the writing control signal produced by the writing control circuit.

9. The semiconductor device according to claim 1, wherein
the first writing circuit comprises:
a delay circuit including an input node and an output node, the input node of the delay circuit being connected to the first input terminal; and a first NOR logical circuit including a plurality of input nodes respectively connected to the second input terminal and the output node of the delay circuit, and including an output node connected to the first output terminal.

10. The semiconductor device according to claim 8, wherein the writing control circuit of the writing unit comprises:
a NAND logical circuit including an output node outputting the writing control signal;
a first inverter circuit including an input node connected to the third input terminal, and an output node connected to one input node of the NAND logical circuit; and
a second inverter circuit including an input node connected to the fourth input terminal, and an output node connected to the other input node of the NAND logical circuit.

11. The semiconductor device according to claim 8, wherein
the second writing circuit of the writing unit comprises:
second and third transistors being of a first conductive type and being connected between a power supply and the second output terminal, a gate of the second transistor being supplied with the writing control signal, and a gate of the third transistor being connected to the fifth input terminal; and
fourth and fifth transistors being of a second conductive type and being connected between the second output terminal and ground, a gate of the fourth transistor being connected to the fifth input terminal via a third inverter circuit, and a gate of the fifth transistor being supplied with the writing control signal.

12. The semiconductor device according to claim 8, wherein
the writing control circuit of the writing unit comprises: a first rewrite node;
a first control unit to which a pre-charge signal, a selection signal, and a write enable signal are supplied; and
a second control unit to which the write data and the control signal are supplied,
the first control unit controls the first rewrite node based on the supplied pre-charge signal, the supplied selection signal, and the supplied write enable signal;
the second control unit generates the writing control signal based on the supplied write data, the supplied control signal, and a potential of the first rewrite node.

13. The semiconductor device according to claim 12, wherein
the second control unit of the writing control circuit of the writing unit comprises:
a second NOR logical circuit outputting the writing control signal; a third NOR logical circuit including a plurality of input nodes connected to the third input terminal, the fourth input terminal, and the first rewrite node respectively, and an output node connected to one input node of the second NOR logical circuit; and
a fourth NOR logical circuit including a plurality of input nodes connected respectively to the first rewrite node, a connecting node connected to the first rewrite node via the fourth inverter circuit and the delay circuit, and an output node connected to the other input node of the second NOR logical circuit.

14. The semiconductor device according to claim 12, wherein the first writing circuit comprises:
a second rewrite node;
a third control unit to which the pre-charge signal and a signal transmitted via and the second line are supplied; and
a fourth control unit to which a signal transmitted via the second line and the control signal are supplied, wherein
the third control unit controls the second rewrite node by the supplied pre-charge signal and the supplied signal transmitted via the second line; and
the fourth control unit controls the first line based on the supplied signal transmitted via the second line, the supplied control signal, and a level of the second rewrite node.

15. The semiconductor device according to claim 14, wherein
the fourth controlling unit of the first writing circuit comprises:
a delay circuit including an input node connected to the first input terminal; and
a fifth NOR logical circuit including a plurality of input nodes connected to the second input terminal, an output node of the delay circuit, and the second rewrite node respectively, and an output node connected to the first output terminal.

16. The semiconductor device according to claim 6, wherein
the sense amplifier circuit of the reading circuit comprises:
a reading current circuit connected to a power supply;
a differential amplifier circuit including one input node connected to one end of the first transistor;
a first switch circuit connected between the reading current circuit and one input node of the differential amplifier circuit, and controlled by the reading pulse signal;
a reference terminal connected to the other input node of the differential amplifier circuit, and receiving a reference voltage; and
a second switch circuit connected between an output node of the differential amplifier circuit and the data latch circuit, and controlled by the reading pulse signal.

17. The semiconductor device according to claim 3, wherein
the first and second lines have hierarchical structures respectively;
the first line includes a global common source line and a local common source line having a lower hierarchy of the global common source line; the second line includes a global bit line and a local bit line having a lower hierarchy of the global bit line;
the local common source line of the first line is connected to the first terminal of the first memory cell;
the local bit line of the second line is connected to the second terminal of the first memory cell;
the first writing circuit is configured to control the global common source line of the first line; and
the writing unit is configured to control the global bit line of the second line.

18. The semiconductor device according to any one of claims 4 to 6 claim 4, further comprising an input-output circuit inserted between the I/O line pair and the first and second input-output terminals of the reading circuit,
wherein
the input-output circuit is configured to provide one of conductive and non-conductive states between the I/O line pair and the first and second input-output terminals in response to a selection signal.

19. The semiconductor device according to claim 1, wherein the memory cell array includes a plurality of memory cells including the first memory cell, and
the memory cells being arranged in a first row and being configured to receive written data arranged in the first row at a same time as each other.

20. The semiconductor device according to claim 1, wherein
the one memory cell comprises a memory cell that includes a variable resistive element of one of STT-RAM (Spin Transfer Torque-Random Access Memory) and Re-RAM (Resistive Random Access Memory).
